(19) United States
(12) Patent Application Publication
(10) Pub. No.: US 2010/0132989 A1
(43) Pub. Date: Jun. 3, 2010

(54) NOVEL POLYIMIDE PRECURSOR COMPOSITION AND USE THEREOF

(76) Inventors: Kan Fujihara, Shiga (JP); Yoshihide Sekito, Shiga (JP); Tetsuya Kogiso, Shiga (JP)

Correspondence Address: NIXON & VANDERHYE, PC, 901 NORTH GLEBE ROAD, 11TH FLOOR, ARLINGTON, VA, 22203, US

(21) Appl. No.: 12/596,027

(22) PCT Filed: Apr. 3, 2008
(86) PCT No.: PCT/JP2008/056701

§ 371 Date: Oct. 15, 2009

(30) Foreign Application Priority Data
Apr. 19, 2007 (JP) 2007-110931
Apr. 19, 2007 (JP) 2007-110935

(51) Int. Cl. H05K 1/00; C08G 18/10; C08J 3/28

(52) U.S. Cl. 174/258; 528/61; 528/59; 522/111

(57) ABSTRACT

An object of the present invention is to provide a polyimide precursor composition solution that (i) uses no siloxane diamine, (ii) is curable at low temperature (not more than 250° C.) and (iii) has low viscosity regardless of its high concentration, and a photosensitive resin composition, photosensitive resin film, a thermosetting resin composition, a polyimide insulating film, and a printed wiring board with an insulating film, each of which has good physical properties and is obtained by use of the polyimide precursor composition solution. The foregoing object is attained by using a polyimide precursor composition solution which includes at least a (A) urethane imide oligomer having a terminal carboxylic acid group and a (B) diamino compound and/or isocyanate compound.

### TECHNICAL FIELD

The present invention relates to a polyimide precursor composition and a thermosetting resin composition, each of which is curable at a low temperature and is suitably usable as insulating material for electric and electronic use, and a photosensitive resin composition developable with an alkaline aqueous solution, which photosensitive resin composition is curable at a low temperature and is suitably usable as insulating material for electric and electronic use. The present invention also relates to a cured film, an insulating film, and a printed wiring board covered with an insulating film, each of which are obtained by use of the polyimide precursor composition, the thermosetting resin composition, or the photosensitive resin composition.

### BACKGROUND ART

Polyimide resin has excellent thermal resistance, electrical insulating property, chemical resistance, and mechanical property, and therefore has been made in use for electric and electronic uses. For example, polyimide resin is used as material for (i) insulating films and protective coating agents provided on a semiconductor device, (ii) surface protective material and base material resin for a flexible circuit board, an integrated circuit and the like, and further (iii) an interlayer insulating film and a protective film for a fine circuit. Particularly, when the polyimide resin is used as coating material to coat a substrate wiring, the polyimide resin is made in use as a cover lay film that is provided by applying an adhesive on a shaped product such as a polyimide film, a liquid cover coat ink of a liquid form made of polyimide resin, and the like.

The polyimide resin solution used in a liquid cover coat ink can be roughly categorized into two types: one type is a polyamic acid solution which is a solution of a polyimide resin precursor, and the other one type is a polyimide solution that uses a polyimide soluble in an organic solvent. However, the polyamic acid solution and the polyimide solution are polymer solutions of a high molecular weight polymer, which have a large molecular weight of solute and are low in solvent solubility. Therefore, it is impossible to prepare these solutions so as to have a high solute concentration. Thus, for example, upon formation of an applied film, a large amount of solvent needs to be volatilized, thereby causing a problem of poor productivity. Moreover, with use of the polyimide resin precursor solution, it is necessary to imidize the film at a temperature exceeding 300° C., after the film is formed. Thus, in a case where the polyimide resin precursor solution is used for example to (i) form a protective film for a flexible substrate or the like or (ii) to apply to a shaped product as an adhesive, it is necessary to encounter such problems as the wiring material not being capable of resisting such a high temperature, and the like. Hence, there has been a demand for a resin that is curable at a temperature that does not cause deterioration of wiring (not more than 250° C.).

Regarding a technique of providing a polyimide resin solution to solve this problem, a polyimide precursor solution having high concentration and low viscosity has been proposed, in which (i) a diamine and (ii) an aromatic tetracarboxylic acid or a diester acid derivative thereof are dissolved (for example, see Patent Literatures 1 to 4).

Moreover, a polyimide precursor solution having high concentration and low viscosity has been disclosed, in which a diamine and a tetracarboxylic acid or its diester are dissolved, which tetracarboxylic acid contains a structural unit that has an amide bonding in the structure (for example, see Patent Literatures 5 to 7).

Furthermore, a photosensitive resin composition or a plasma etching resist that uses an imide siloxane oligomer having a half-esterified terminal has been proposed (for example, see Patent Literatures 8 to 11).

### Citation List

Patent Literature 1

Japanese Patent Application Publication, Tokukaihei, No. 11-209609 A (Publication Date: Aug. 3, 1999)

Patent Literature 2

Japanese Patent Application Publication, Tokukaihei, No. 11-217502 A (Publication Date: Aug. 10, 1999)

Patent Literature 3

Japanese Patent Application Publication, Tokukai, No. 2000-319389 A (Publication Date: Nov. 21, 2000)

Patent Literature 4

Japanese Patent Application Publication, Tokukai, No. 2000-319391 (Publication Date: Nov. 21, 2000)

Patent Literature 5

Japanese Patent Application Publication, Tokukai, No. 2001-31764 (Publication Date: Feb. 6, 2001)

Patent Literature 6

Japanese Patent Application Publication, Tokukai, No. 2001-163974 (Publication Date: Jun. 19, 2001)

Patent Literature 7

Japanese Patent Application Publication, Tokukai, No. 2000-234023 (Publication Date: Aug. 29, 2000)

Patent Literature 8

Japanese Patent Application Publication, Tokukai, No. 2000-212446 (Publication Date: Aug. 2, 2000)

Patent Literature 9

Japanese Patent Application Publication, Tokukai, No. 2001-89656 (Publication Date: Apr. 3, 2001)

Patent Literature 10

Japanese Patent Application Publication, Tokukai, No. 2001-125273 (Publication Date: May 11, 2001)

Patent Literature 11

Japanese Patent Application Publication, Tokukai, No. 2001-215702 (Publication Date: Aug. 10, 2001)

### SUMMARY OF INVENTION

### Technical Problem

The foregoing Patent Literatures disclose various methods for preparing a polyimide resin solution in high concentration. However, the solutions disclosed in Patent Literatures 1 to 4 that use (i) a diamine and (ii) an aromatic tetracarboxylic acid or its diester acid derivative have an extremely high imidization temperature. Therefore, it is impossible to provide a polyimide precursor solution that is curable at a low temperature. Moreover, in the polyimide precursor solution disclosed in Patent Literature 5 to 7, (i) a diamine and (ii) a tetracarboxylic acid or its diester are dissolved, which tetracarboxylic acid contains a structural unit that has an amide bond that easily breaks. Thus, the polyimide precursor solution has poor stability. As a result, particularly in a case where the solution is prepared to have a high concentration, a problem occurs that a solution viscosity changes with time caused by breakage of an amide bond. When a cured film formed from a resin composition that contains an imide siloxane oligomer having a half-esterified terminal as disclosed in Patent Literatures 8 to 11 is used as circuit board material, a bleedout of impurities contained in the siloxane diamine occurs on the cured film, thereby causing a problem of malfunction of a semiconductor. Moreover, when the cured film formed from the resin composition containing the imide siloxane oligomer having a half-esterified terminal is used as the circuit board material, wettability of the cured film surface is poor, thereby causing poor adhesion properties with various sealing agents.

In view of the foregoing conditions, an object of the present invention is to provide: a polyimide precursor composition which (i) uses no siloxane diamine, (ii) is curable at a low temperature of not more than 250° C., more preferably not more than 200° C., and (iii) is preparable as a polyimide precursor composition solution with low viscosity, regardless of its high concentration; and a photosensitive resin composition, a photosensitive resin film, a thermosetting resin composition, a thermosetting resin film, a polyimide insulating film, and a printed wiring board with an insulating film, each of which has good physical properties and is obtained by use of the polyimide precursor composition.

### Solution to Problem

As a result of diligent study to attain the above object, the inventors found that a polyimide cured film which is curable at a low temperature and has good physical properties is obtainable without including siloxane diamine by use of a composition including a urethane imide oligomer having (i) a terminal carboxylic acid group and (ii) a diamino compound and/or isocyanate compound. In other words, the inventors arrived at a fact that a polyimide precursor composition solution containing a (A) urethane imide oligomer having a terminal carboxylic acid group and a (B) diamino compound and/or isocyanate compound exhibits low viscosity even if the solution is prepared to have a high concentration of solute dissolved therein, and that a polyimide cured film that has good physical properties is obtainable from such a polyimide precursor composition solution. Based on such knowledge, the inventors accomplished the present invention. The present invention attains the object by use of a novel polyimide precursor composition of a novel structure, as described below.

Namely, a polyimide precursor composition in accordance with the present invention includes at least: a (A) urethane imide oligomer having a terminal carboxylic acid group; and a (B) diamino compound and/or isocyanate compound.

With the polyimide precursor composition according to the present invention, it is preferable that the (A) urethane imide oligomer having a terminal carboxylic acid group is a tetracarboxylic acid urethane imide oligomer.

Moreover, the polyimide precursor composition according to the present invention is preferably arranged in such a manner that the (A) urethane imide oligomer having a terminal carboxylic acid group is obtainable by (i) reacting at least a (a) diol compound and a (b) diisocyanate compound so as to synthesize a terminal isocyanate compound, (ii) reacting the synthesized terminal isocyanate compound with a (c) tetracarboxylic acid dianhydride represented by a general formula (3) so as to synthesize a urethane imide oligomer having a terminal acid anhydride, and (iii) reacting the synthesized urethane imide oligomer having a terminal acid anhydride with (d) water and/or primary alcohol, the (a) diol compound being represented by the following general formula (1):

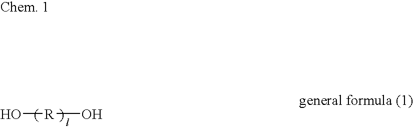

where R denotes a bivalent organic group; and 1 denotes an integer of 1 to 20, the (b) diisocyanate compound being represented by the following general formula (2):

Chem. 2

O═C═N—X—N═C═O general formula (2)

where X denotes a bivalent organic group, and the (c) tetracarboxylic acid dianhydride being represented by the following general formula (3):

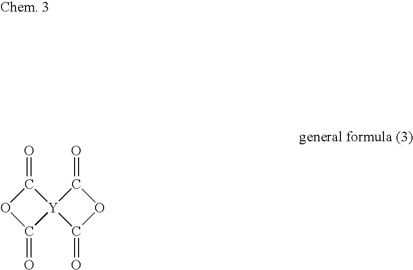

where Y denotes a quadrivalent organic group.

Moreover, with the polyimide precursor composition according to the present invention, it is preferable that the (a) dial compound includes at least a polycarbonate diol represented by the following general formula (4):

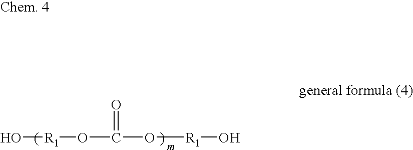

where each R₁ independently denote a bivalent organic group; and m denotes an integer of 1 to 20.

With the polyimide precursor composition according to the present invention, it is preferable that the (A) urethane imide oligomer having a terminal carboxylic acid group further includes a carboxyl group in its side chain.

A photosensitive resin composition according to the present invention includes at least: the foregoing polyimide precursor composition; a (C) photosensitive resin; and a (D) photopolymerization initiator.

With the photosensitive resin composition according to the present invention, it is preferable that the (A) urethane imide oligomer having a terminal carboxylic acid group, the (B) diamino compound and/or isocyanate compound, the (C) photosensitive resin, and the (D) photopolymerization initiator are included in the photosensitive resin composition in such a manner that the (C) photosensitive resin is included by 10 parts by weight to 200 parts by weight and the (D) photopolymerization initiator is included by 0.1 parts by weight to 50 parts by weight, with respect to a total solid content of the (A) urethane imide oligomer having a terminal carboxylic acid and the (B) diamino compound and/or isocyanate compound being 100 parts by weight.

Moreover, the photosensitive resin composition according to the present invention preferably further includes a (E) thermosetting resin.

The photosensitive resin composition is preferably arranged in such a manner that the (E) thermosetting resin is comprised by 0.5 parts by weight to 100 parts by weight, with respect to a total solid content of the (A) urethane imide oligomer having a terminal carboxylic acid group, the (B) diamino compound and/or isocyanate compound, the (C) photosensitive resin, and the (D) photopolymerization initiator being 100 parts by weight.

A thermosetting resin composition according to the present invention includes at least: the foregoing polyimide precursor composition; and a (E) thermosetting resin.

With the thermosetting resin composition according to the present invention, it is preferable that the (E) thermosetting resin is comprised by 0.5 parts by weight to 100 parts by weight, with respect to a total solid content of the (A) urethane imide oligomer having a terminal carboxylic acid group, and the (B) diamino compound and/or isocyanate compound being 100 parts by weight.

A polyimide precursor composition solution according to the present invention is obtained by dissolving into an organic solvent the polyimide precursor composition, the photosensitive resin composition, or the thermosetting resin composition.

A resin film according to the present invention is obtained by (i) applying the polyimide precursor composition solution to a substrate surface, then (ii) drying the applied solution.

An insulating film according to the present invention is obtained by curing the resin film.

A printed wiring board with an insulating film according to the present invention is produced by covering a printed wiring board with the insulating film.

### ADVANTAGEOUS EFFECTS OF INVENTION

As described above, a polyimide precursor composition of the present invention includes at least a (A) urethane imide oligomer having a terminal carboxylic acid and a (B) diamino compound and/or isocyanate compound. Thus, in a case where the polyimide precursor composition is dissolved in an organic solvent, an obtained solution has low viscosity, regardless of its high concentration of the solute in the solution. A polyimide cured film prepared from the polyimide precursor composition of the present invention has excellent adhesiveness, environmental test stability, chemical resistance, flexibility, and wettability in an applied film, and has good physical properties. Therefore, the polyimide precursor composition of the present invention is usable and attains excellent effects for protective films or the like of various circuit boards. Moreover, a photosensitive resin composition and a thermosetting resin composition, each of which use the polyimide precursor composition of the present invention, (i) use no siloxane diamine, (ii) are curable at a low temperature, and (iii) express various excellent properties upon application and shaping on a wiring board.

### DESCRIPTION OF EMBODIMENTS

The following description specifically explains, in accordance with the present invention, (I) Polyimide Precursor Composition, (II) Photosensitive Resin Composition, (III) Thermosetting Resin Composition, (IV) Polyimide Precursor Composition Solution, and (V) Method for Using Polyimide Precursor Composition, in this order.

(I) Polyimide Precursor Composition

A polyimide precursor composition of the present invention includes at least a (A) urethane imide oligomer having a terminal carboxylic acid group; and a (B) diamino compound and/or isocyanate compound. The polyimide precursor composition of the present invention is a polyimide precursor composition which includes a (A) urethane imide oligomer having a terminal carboxylic acid group and a (B) diamino compound and/or isocyatane compound, and denotes a mixture of (A) and (B) that has no covalent bond formed between (A) and (B). That is to say, although a general polyimide precursor composition represents, for example, a composition including a polymer in which a tetracarboxylic acid dianhydride is partially binded covalently to a diamino compound via an amide bond, the polyimide precursor composition of the present invention denotes a polyimide precursor composition in which (A) and (B) form no covalent bond. Such a polyimide precursor composition that has no covalent bond makes it possible to increase concentration of a solution in which the (A) and (B) are dissolved, and makes it difficult for a viscosity of the solution to change with time (change in molar mass) during storage of the polyimide precursor composition solution.

(I-1) (A) Urethane Imide Oligomer Having Terminal Carboxylic Acid Group

A urethane imide oligomer having a terminal carboxylic acid group, which is used in the present invention, is an oligomer in which (i) at least one carboxylic acid group is provided on its end, (ii) a urethane structure is included therein, (iii) an imide ring is closed, and (iv) its number-average molecular weight is not more than 30,000, more preferably not more than 20,000, based on polyethylene glycol.

More specifically, in the present invention, the (A) urethane imide oligomer having a terminal carboxylic acid is a compound which (i) has no siloxane bond in its main chain skeleton, (ii) has at least one repeating unit that has a urethane bond, which repeating unit is represented by the following general formula (5):

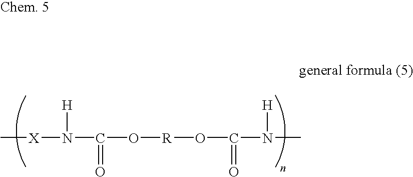

where each R and X independently denotes a bivalent organic group; and n denotes an integer of not less than 1, and (iii) has a structure having at least two imide bonds and at least one carboxyl group on its end, which structure is represented by the following general formula (6):

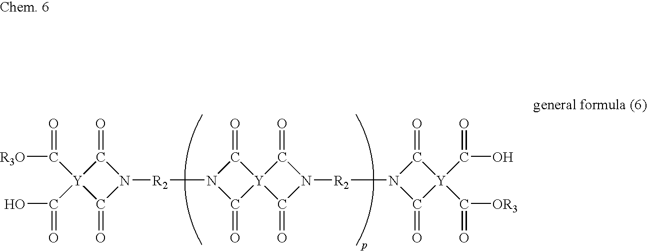

where each R₂ independently denotes a bivalent organic group; each R₃ independently denotes a hydrogen atom or an alkyl group; each Y independently denotes a quadrivalent organic group; and p denotes an integer of not less than 0.

Moreover, the number-average molecular weight of the urethane imide oligmer having a terminal carboxylic acid group of the present invention is preferably not more than 30,000, more preferably not more than 20,000, and particularly preferably not more than 15,000, based on polyethylene glycol. It is preferable to carry out a reaction while controlling the number-average molecular weight in the above range since such a control improves solubility in an organic solvent of the urethane imide oligomer having a terminal carboxylic acid group.

Since the urethane imide oligomer having a terminal carboxylic acid group has no siloxane bond in its structure, a surface of a cured film made by use of the urethane imide oligomer has excellent wettability, and therefore has good adhesiveness with various sealing agents. Further, the bond in the structure is not an amide bond but an imide bond; this attains excellent storage stability. As a result, it is possible to prevent a solution viscosity to change with time, in a case where a polyimide precursor composition solution is prepared and then stored.

The (A) urethane imide oligomer having a terminal carboxylic acid group used in the present invention is not particularly limited as long as the foregoing structure is included. However, it is more preferable to obtain the urethane imide oligomer having a terminal carboxylic acid group by the following method:

reacting at least a (a) diol compound represented by the following general formula (1):

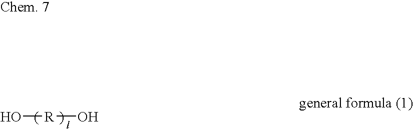

where R denotes a bivalent organic group; and 1 denotes an integer of 1 to 20 with a (b) diisocyanate compound represented by the following general formula (2):

Chem. 8

O═C═N—X—N═C═O general formula (2)

where X denotes a bivalent organic group, so as to synthesize a terminal isocyanate compound;
reacting the terminal isocyanate compound with a (c) tetracarboxylic acid dianhydride represented by the following general formula (3):

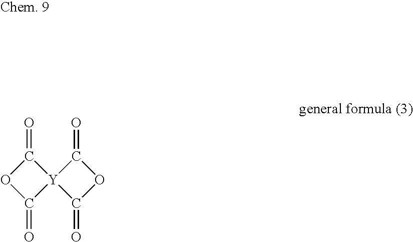

where Y denotes a quadrivalent group, so as to synthesize a urethane imide oligomer having a terminal acid anhydride; and
reacting the urethane imide oligomer having a terminal acid anhydride with (d) (water and/or a primary alcohol).

<(a) Diol Compound>

The (a) diol compound that is used in the present invention is a branched or a straight-chained compound represented by the general formula (1), including two hydroxyl groups in a molecule. The (a) diol compound is not particularly limited as long as the compound has the foregoing arrangement, and examples thereof encompass: alkylene diols such as ethylene glycol, diethylene glycol, propylene glycol, 1,3-butanediol, 1,4-butanediol, 1,5-pentanediol, neopentyl glycol, 3-methyl-1,5-pentanediol, 1,6-hexanediol, 1,8-octanediol, 2-methyl-1,8-octanediol, 1,9-nonanediol, 1,10-decandiol, 1,4-cyclohexanediol, and 1,4-cyclohexane dimethanol; diols containing a carboxyl group, such as dimethylolpropionic acid (2,2-bis(hydroxymethyl)propionic acid), dimethylol butanoic acid (2,2-bis(hydroxymethyl)butanoic acid), 2,3-dihydroxybenzoic acid, 2,4-dihydroxybenzoic acid, 2,5-dihydroxybenzoic acid, 2,6-dihydroxybenzoic acid, 3,4-dihydroxybenzoic acid, and 3,5-dihydroxybenzoic acid; polyoxyalkylene diols such as polyethylene glycol, polypropylene glycol, polytetramethylene glycol, a random copolymer of tetramethylene glycol and neopentyl glycol; a polyester diol obtained by reacting a polyhydric alcohol and a polybasic acid; a polycarbonate diol having a carbonate skeleton; a polycaprolactone diol obtained by carrying out ring opening addition of lactones such as γ-butyl lactone, ε-caprolactone, and δ-valerolactone; a bisphenol A, an ethylene oxide adduct of a bisphenol A, a propylene oxide adduct of a bisphenol A, a hydrogenated bisphenol A, an ethylene oxide adduct of a hydrogenated bisphenol A, and a propylene oxide adduct of a hydrogenated bisphenol A. These compounds can be used solely or two or more types can be used in combination.

It is particularly preferable to use, as the (a) diol compound, a polycarbonate diol represented by the following general formula (4):

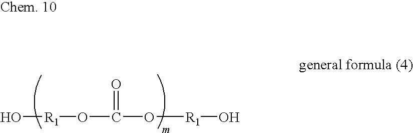

where, each R₁ independently denotes a bivalent organic group; and m denotes an integer of 1 to 20.
Such a polycarbonate dial is preferable since thermal resistance, flexibility, water resistance, chemical resistance, and electrical insulating reliability under high temperature and moisture, each of a cured film obtained therefrom can be further improved.

Specific examples of the polycarbonate diol encompass the following commercial products: product names PCDL T-4671, T-4672, T-4691, T-4692, T-5650J, T-5651, T-5652, T-6001, and T-6002, each of which are manufactured by Asahi Kasei Chemicals Corporation; product names PLACCEL CD CD205, CD205PL, CD205HL, CD210, CD210PL, CD210HL, CD220, CD220PL, and CD220HL, each of which are manufactured by Daicel Chemical Industries, Ltd.; product names Kuraray Polyol C-1015N, C-1050, C-1065N, C-1090, C-2015N, C-2065N, and C-2090, each of which are manufactured by Kuraray Co., Ltd.; and product names NIPPOLLAN 981, 980R, and 982R, each of which are manufactured by Nippon Polyurethene Industry Co., Ltd. Each of these products can be used solely, or two or more types thereof can be used in combination. The polycarbonate diol preferably has a number-average molecular weight of 500 to 5000, more preferably 750 to 2500, and particularly preferably 1000 to 2000, based on polystyrene. It is preferable to have the number-average molecular weight to be in the foregoing range since chemical resistance and flexibility of an obtainable cured film can be improved. If the number-average molecular weight is less than 500, the flexibility of the obtained cured film may decrease, and if the number-average molecular weight is not less than 5000, solubility in a solvent of the urethane imide oligomer having a terminal carboxylic acid group may decrease.

Further preferably, it is also possible to introduce a carboxyl group to a side chain of the urethane imide oligomer having a terminal carboxylic acid group by using in combination the polycarbonate diol and a diol containing a carboxyl group. This increases a number of branched points in a main chain of the urethane imide oligomer having a terminal carboxylic acid group, thereby decreasing crystallinity. Hence, a solvent solubility of the urethane imide oligomer having a terminal carboxylic acid group improves, therefore is preferable in this view.

<(b) Diisocyanate Compound>

The (b) diisocyanate compound used in the present invention is a compound represented by the general formula (2), of which two isocyanate groups are included in a molecule.

Examples of the (b) diisocyanate compound encompass: aromatic diisocyanate compounds such as diphenylmethane-2,4′-diisocyanate, 3,2′- or 3,3′- or 4,2′- or 4,3′- or 5,2′- or 5,3′- or 6,2′- or 6,3′-dimethyl diphenylmethane-2,4′-diisocyanate, 3,2′- or 3,3′- or 4,2′- or 4,3′- or 5,2′- or 5,3′-6,2′- or 6,3′-diethyl diphenylmethane-2,4′-diisocyanate, 3,2′- or 3,3′- or 4,2′- or 4,3′- or 5,2′- or 5,3′- or 6,2′- or 6,3′-dimethoxy diphenylmethane-2,4′-diisocyanate, diphenylmethane-4,4′-diisocyanate, diphenylmethane-3,3′-diisocyanate, diphenylmethane-3,4′-diisocyanate, diphenyl ether-4,4′-diisocyanate, benzophenone-4,4′-diisocyanate, diphenyl sulfone-4,4′diisocyanate, tolylene-2,4-diisocyanate, tolylene-2,6-diisocyanate, m-xylylene diisocyanate, p-xylylene diisocyanate, naphthalene-2,6-diisocyanate, and 4,4′-[2,2-bis(4-phenoxyphenyl)propane]diisocyanate; alicyclic diisocyanate compounds such as hydrogenated diphenylmethane diisocyanate, hydrogenated xylylene diisocyanate, isophorone diisocyanate, and norbornene diisocyanate; and aliphatic diisocyanate compounds such as hexamethylene diisocyanate, trimethyl hexamethylene diisocyanate, and lysine diisocyanate. Each of these compounds can be used solely, or two or more types thereof can be used in combination. It is preferable to use the foregoing compounds to improve thermal resistance of an obtainable cured film. Moreover, a compound that is stabilized with a blocking agent that is required for avoiding change with time can also be used. Examples of the blocking agent are alcohol, phenol, oxime or the like, however there is no particular limit in the blocking agent thus used.

It is particularly preferable to use, as the (b) diisocyanate compound, diphenylmethane-4,4′-diisocyanate, diphenylmethane-3,3′-diisocyanate, diphenylmethane-3,4′-diisocyanate, tolylene-2,4-diisocyanate, tolylene-2,6-diisocyanate, or norbonene diisocyanate. It is preferable to use such a diisocyanate compound since a thermal resistance and a water resistance of an obtainable cured resin can be further improved.

Moreover, in order to improve developing properties of a photosensitive resin composition, tolylene-2,6-diisocyanate, tolylene-2,4-diisocyanate, or 1,6-hexamethylene diisocyanate is suitably used as the (b) diisocyanate compound.

<Synthesis Method of Terminal Isocyanate Compound>

The following synthesis method of synthesizing the terminal isocyanate compound is used in the present invention: The synthesis method comprises reacting a (a) dial compound and a (b) diisocyanate compound without a solvent or in an organic solvent. In the reaction, the diol compound and the diisocyanate compound are added in such amounts that satisfy that the number of hydroxyl groups/the number of isocyanate groups (isocyanate group/hydroxyl group)=not less than 1 but not more than 2.10, more preferably not less than 1.10 but not more than 2.10, and further preferably not less than 1.90 but not more than 2.10.

When two or more types of the (a) diol compound is used, the reaction with the (b) diisocyanate compound can be carried out after the two or more types of (a) diol compounds are mixed, or the (b) diisocyanate compound can be reacted with each of the (a) diol compounds separately. The reaction also can be carried out in such a manner that (i) a (a) diol compound and the (b) diisocyanate compound are first reacted, (ii) a terminal isocyanate compound thus obtained is further reacted with another (a) diol compound, and (iii) this reactant is further reacted with the (b) diisocyanate compound. The same applies with a case where two or more types of (b) diisocyanate compounds are used. In these ways, a desired terminal isocyanate compound is produced.

A temperature for reacting (a) and (b) is preferably in a range of 40° C. to 160° C., and is more preferably in a range of 60° C. to 150° C. If the temperature is less than 40° C., the reaction would take too much time, and if the temperature exceeds 160° C., a three-dimensional reaction occurs during the synthesis reaction, which causes gelation to easily occur. How long the reaction is carried out for can be appropriately selected based on a batch scale and an employed reaction condition. The reaction may also be carried out in the presence of a catalyst such as tertiary amines, a metal or semi-metal compound, for example alkaline metals, alkaline earth metals, tin, zinc, titanium, or cobalt.

Although the reaction can be carried out without a solvent, it is preferable to carry out the reaction in an organic solvent system, to have control of the reaction. Examples of the organic solvent used encompass: sulfoxide-based solvents such as dimethyl sulfoxide and diethyl sulfoxide; formamide-based solvents such as N,N-dimethyl formamide and N,N-diethyl formamide; acetamide-based solvents such as N,N-dimethylacetamide and N,N-diethylacetamide; pyrrolidone-based solvents such as N-methyl-2-pyrrolidone and N-vinyl-2-pyrrolidone; phenol-based solvents such as phenol, o-, m-, or p-cresol, xylenol, halogenated phenol, and catechol; hexamethylphosphoramide, and γ-butylolactone. Furthermore, these organic polar solvents and an aromatic hydrocarbon such as xylene or toluene can be used in combination, if necessary.

Furthermore, solvents exemplified as follows can also be used: symmetric glycol diethers such as methyl monoglyme (1,2-dimethoxyethane), methyl diglyme (bis(2-methoxyethyl)ether), methyl triglyme (1,2-bis(2-methoxyethoxy)ethane), methyl tetraglyme (bis[2-(2-methoxyethoxyethyl)]ether), ethyl monoglyme (1,2-diethoxyetane), ethyl diglyme (bis(2-ethoxyethyl)ether), and butyl diglyme (bis(2-butoxyethyl)ether); acetates such as methyl acetate, ethyl acetate, isopropyl acetate, n-propyl acetate, butyl acetate, propylene glycol monomethyl ether acetate, ethylene glycol monobutyl ether acetate, diethylene glycol monoethyl ether acetate (another name: Carbitol acetate, 2-(2-butoxyethoxy)ethyl)acetate), diethylene glycol monobutyl ether acetate, 3-methoxybutyl acetate, ethylene glycol monomethyl ether acetate, ethylene glycol monoethyl ether acetate, dipropylene glycol methyl ether acetate, propylene glycol diacetate, and 1,3-butylene glycol diacetate; and ethers such as dipropylene glycol methyl ether, tripropylene glycol methyl ether, propylene glycol n-propyl ether, dipropylene glycol n-propyl ether, propylene glycol n-butyl ether, dipropylene glycol n-butyl ether, tripylene glycol n-propyl ether, propylene glycol phenyl ether, dipropylene glycol dimethyl ether, 1,3-dioxolane, ethylene glycol monobutyl ether, diethylene glycol monoethyl ether, diethylene glycol monobutyl ether, and ethylene glycol monoethyl ether. Of these solvents, it is preferable to use the symmetric glycol diethers, since a side reaction cannot easily occur.

An amount of solvent to be used in a reaction is preferably such an amount that a solute weight concentration in a reaction solution, i.e., a solution concentration, is not less than 5% by weight but not more than 90% by weight. The solute weight concentration in the reaction solution is further preferably in a range of not less than 10% by weight to not more than 80% by weight. If the solution concentration is not more than 5%, it becomes difficult to carry out the polymerization reaction, which therefore causes a decrease in reaction rate, and further may result in not obtaining a substance with a desired structure. Thus, such a solution is not preferred.

Moreover, with the terminal isocyanate compound obtained as a result of the foregoing reaction, an isocyanate group of a resin terminal can be blocked after termination of the synthesis reaction, by use of a blocking agent such as an alcohol, lactam, oxime or the like.

<Synthesis Method of Urethane Imide Oligomer Having Terminal Acid Anhydride>

A urethane imide oligomer having a terminal acid anhydride, which is used in the present invention, is obtained by further reacting the obtained terminal isocyanate compound with a tetracarboxylic acid dianhydride. In the reaction, the terminal isocyanate compound and the tetracarboxylic acid dianhydride are added in such amounts that satisfy the ratio of the number of dianhydride groups to the number of isocyanate groups (dianhydride groups/isocyanate groups)=preferably not more than 2.10, more preferably not less than 1.10 and not more than 2.10, and further preferably not less than 1.90 and not more than 2.10. Moreover, in the reaction of the terminal isocyanate compound and the tetracarboxylic acid dianhydride, a solvent that was used when synthesizing the terminal isocyanate compound can be used, or a foregoing solvent can be further added to such a solvent.

<Tetracarboxylic Acid Dianhydride>

Examples usable as the tetracarboxylic acid dianhydride used for synthesis of a urethane imide oligomer having a terminal acid anhydride in the present invention encompass: 3,3′,4,4′-benzophenone tetracarboxylic acid dianhydride, pyromellitic acid dianhydride, 3,3′,4,4′-oxydiphthalic acid dianhydride, 2,2-bis[4-(3,4-dicarboxylphenoxy)phenyl]propane dianhydride, 2,2-bis(4-hydroxyphenyl)propane dibenzoate-3,3′4,4′-tetracarboxylic acid dianhydride, 3,3′,4,4′-diphenyl sulfone tetracarboxylic acid dianhydride, 3,3′,4,4′-biphenyltetracarboxylic acid dianhydride, 2,3,3′,4-biphenyltetracarboxylic acid dianhydride, and 5-(2,5-dioxotetrahydro-3-furanyl)-3-methyl-3-cyclohexene-1,2-dicarboxylic acid anhydride.

The tetracarboxylic acid dianhydride used for synthesis of the urethane imide oligomer having a terminal acid anhydride is, more preferably, 2,2-bis[4-(3,4-dicarboxyphenoxy)phenyl]propane dianhydride, 3,3′,4,4′-diphenyl sulfone tetracarboxylic acid dianhydride, or 3,3′,4,4′-oxydiphthalic acid dianhydride. Use of such dianhydrides allows improvement in solubility in an organic solvent of the obtained urethane imide oligomer having a terminal carboxylic acid group. Further, use of such dianhydrides is preferable in view of improving chemical resistance of an obtainable cured film.

Moreover, it is further preferable to use as the tetracarboxylic acid dianhydride, 2,2-bis[3,4-dicarboxyphenoxy]pheyl]propane dianhydride, or 5-(2,5-dioxotetrahydro-3-furanyl)-3-methyl-3-cyclohexene-1,2-dicarboxylic acid anhydride, in view of compatibility with other material in a polyimide precursor composition, a photosensitive resin composition, or a thermosetting resin composition.

An amount used of the tetracarboxylic acid dianhydride in the present invention is preferably in a range of not less than 1.50 mol to not more than 2.50 mol, per one mol of polyol (more specifically, a diol compound) used for manufacturing the terminal isocyanate compound, in view of providing a carboxyl group on both terminals of a urethane imide oligomer having a terminal carboxylic acid group. A particularly preferable range of the amount used is not less than 1.90 mol to not more than 2.10 mol per one mol of polyol. This makes it is possible to reduce an amount of tetracarboxylic acid dianhydride that is not associated with the reaction, and therefore is preferable.

<Method for Producing Urethane Imide Oligomer Having Terminal Acid Anhydride>

Various methods are usable as a method for reacting a terminal isocyanate compound and a tetracarboxylic acid dianhydride, for the method for producing the urethane imide oligomer having a terminal acid anhydride. Typical methods thereof are as described below. However, as long as the method provides a tetracarboxylic acid dianhydride on an end of the urethane imide oligomer, any method is usable.

Method 1: Tetracarboxylic acid dianhydride is dispersed or dissolved in an organic solvent, and a terminal isocyanate compound is gradually added to this mixture. A reaction temperature at this time is not less than 100° C. but not more than 300° C., more preferably not less than 140° C. but not more than 250° C. It is preferable for the reaction to occur at the same time as the application of heat and addition of the terminal isocyanate compound, so as to proceed with the imidization. However, it is also possible to use a method in which the terminal isocyanate compound and the tetracarboxylic acid dianhydride are completely dissolved at a low temperature, and then this mixture is heated to a high temperature so as to imidize the solution.

Method 2: Tetracarboxylic acid dianhydride is dispersed or dissolved in an organic solvent, and thereafter a terminal isocyanate compound is gradually added and dissolved in the mixture. The solution thus evenly dissolved is heated, dried and vacuumed in a vacuum drier heated to not less than 100° C. to not more than 250° C., so as to imidize the solution.

<Synthesis of Urethane Imide Oligomer Having Terminal Carboxylic Acid Group>

A urethane imide oligomer having a terminal carboxylic acid group is obtainable by reacting water and/or a primary alcohol with the urethane imide oligomer having a terminal acid anhydride thus obtained by the foregoing method. The primary alcohol is not particularly limited, however, for example, methanol, ethanol, propanol, or buthanol are suitably used.

It is preferable to react the urethane imide oligomer having a terminal acid anhydride with water and/or a primary alcohol by adding the water and/or the primary alcohol to the urethane imide oligomer having a terminal acid anhydride in a proportion of not less than 2.0 times more but not more than 300 times more, more preferably not less than 2.0 times more but not more than 200 times more, than a molar quantity of the tetracarboxylic acid dianhydride used for producing the urethane imide oligomer having a terminal acid anhydride, and thereby carrying out ring-opening of the tetracarboxylic acid dianhydride. The reaction can be carried out without a solvent, however may also be carried out by use of a solvent, such as: a sulfoxide-based solvent such as a dimethyl sulfoxide or a diethyl sulfoxide; a formamide-based solvent such as N,N-dimethyl formamide or N,N-diethyl formamide; an acetamide-based solvent such as N,N-dimethylacetamide or N,N-diethylacetamide; a pyrrolidone-based solvent such as N-methyl-2-pyrrolidone or N-vinyl-2-pyrrolidone; a phenol-based solvent such as phenol, o-, m-, or p-cresol, xylenol, halogenated phenol, or catechol; or a symmetric glycol diether such as hexamethylphosphoramide, γ-butyrolactone, methyl monoglyme (1,2-dimethoxyethane), methyl diglyme (bis(2-methoxyethyl)ether), methyl triglyme (1,2-bis(2-methoxyethoxy)ethane), methyl tetraglyme (bis[2-(2-methoxyethoxyethyl)]ether), ethyl monoglyme (1,2-diethoxyetane), ethyl diglyme (bis(2-ethoxyethyl)ether), or butyl diglyme (bis(2-butoxyethyl)ether); an acetate such as γ-butyrolactone, N-methyl-2-pyrrolidone, methyl acetate, ethyl acetate, isopropyl acetate, n-propyl acetate, butyl acetate, propylene glycol monomethyl ether acetate, ethylene glycol monobutyl ether acetate, diethylene glycol monoethyl ether acetate (another name: Carbitol acetate, 2-(2-butoxyethoxy)ethyl)acetate), diethylene glycol monobutyl ether acetate, 3-methoxybutyl acetate, ethylene glycol monomethyl ether acetate, ethylene glycol monoethyl ether acetate, dipropylene glycol methyl ether acetate, propylene glycol diacetate, or 1,3-butylene glycol diacetate; or an ether such as dipropylene glycol methyl ether, tripropylene glycol methyl ether, propylene glycol n-propyl ether, dipropylene glycol n-propyl ether, propylene glycol n-butyl ether, dipropylene glycol n-butyl ether, tripylene glycol n-propyl ether, propylene glycol phenyl ether, dipropylene glycol dimethyl ether, 1,3-dioxolane, ethylene glycol monobutyl ether, diethylene glycol monoethyl ether, diethylene glycol monobutyl ether, or ethylene glycol monoethyl ether. If necessary, hexane, acetone, toluene, xylene or the like that have low-boiling points can also be used in combination. Among the foregoing solvents, the symmetric glycol diethers have a high oligomer solubility, and therefore is preferable.

It is preferable in the reaction that heat is applied in such a range that the water and/or the primary alcohol thus added does not go beyond a range of a reaction system, and is preferably heated to a temperature range of not less than 20° C. to not more than 150° C., and an upper limit is more preferably not more than 120° C. This makes it easier to promote the reaction. The more amount of water and/or primary alcohol added the more preferable, however if too much of the water and/or primary alcohol is added, solubility of other additive resins decreases. Hence, it is preferable to remove any non-reacting water and/or primary alcohol after the reaction. A temperature at the time of removing the non-reacting water and/or primary alcohol after the reaction is preferably not less than a boiling point of the added water and/or the primary alcohol. By heating to such a temperature, the non-reacting water and/or primary alcohol is removed out of the system.

(I-2) (B) Diamino Compound and/or Isocyanate Compound

The diamino compound to be used as component (B) in the present invention is a compound which includes two or more amino groups. Preferably, the diamino compound is an aromatic diamine represented by the following general formula (7):

Chem. 11

H₂N—R₄—NH₂ general formula (7)

where R₄ is a bivalent organic group.

More specifically, examples of the diamino compound encompass: diamino phenols such as m-phenylenediamine, o-phenylenediamine, p-phenylenediamine, m-aminobenzylamine, p-aminobenzylamine, bis(3 aminophenyl)sulfide, (3-aminophenyl)(4-aminophenyl)sulfide, bis(4-aminophenyl)sulfide, bis(3-aminophenyl)sulfoxide, (3-aminophenyl)(4-aminophenyl)sulfoxide, bis(4-aminophenyl)sulfoxide, bis(3-aminophenyl)sulfone, (3-aminophenyl)(4-aminophenyl)sulfone, bis(4-aminophenyl)sulfone, 3,4′-diaminobenzaphenone, 4,4′-diaminobenzophenone, 3,3′-diaminobenzophenone, 3,3′-diaminodiphenylmethane, 3,4′-diaminodiphenylmethane, 4,4′-diaminodiphenylmethane, 4,4′-diaminodiphenylether, 3,3′-diaminodiphenylether, 3,4′-diaminodiphenylether, bis[4-(3-aminophenoxy)phenyl]sulfoxide, bis[4-(aminophenoxy)phenyl]sulfoxide, (4-aminophenoxyphenyl)(3-aminophenoxyphenyl)phenyl]sulfoxide, bis[4-(3-aminophenoxy)phenyl]sulfone, bis[4-(4-aminophenoxy)phenyl]sulfone, (4-aminophenoxyphenyl)(3-aminophenoxyphenyl)phenyl]sulfone, bis[4-(3-aminophenoxy)phenyl]sulfide, bis[4-aminophenoxy]phenyl]sulfide, (4-aminophenoxyphenyl)(3-aminophenoxyphenyl)phenyl]sulfide, 3,3′-diaminobenzanilide, 3,4′-diaminobenzanilide, 4,4′-diaminobenzanilide, bis[4-(3-aminophenoxy)phenyl]methane, bis[4-(4-aminophenoxy)phenyl]methane, [4-(4-aminophenoxyphenyl)][4-(3-aminophenoxyphenyl)]methane, 1,1-bis[4-(3-aminophenoxy)phenyl]ethane, 1,1-bis[4-(4-aminophenoxy)phenyl]ethane, 1,1-[4-(4-aminophenoxyphenyl)][4-(3-aminophenoxyphenyl)]ethane, 1,2-bis[4-(3-aminophenoxy)phenyl]ethane 1,2-bis[4-(4-aminophenoxy)phenyl]ethane, 1,2-[4-(4-aminophenoxyphenyl)][4-(3-aminophenoxyphenyl)]ethane, 2′2-bis[4-(3-aminophenoxy)phenyl]propane 2,2-bis[4-(4-aminophenoxy)phenyl]propane, 2,2-bis[4-(4-aminophenoxyphenyl)][4-(3-aminophenoxyphenyl)]propane, 2,2-bis[3-(3-aminophenoxy)phenyl]-1,1,1,3,3,3-hexafluoropropane, 2,2-bis[4-(4-aminophenoxy)phenyl]-1,1,1,3,3,3-hexafluoropropane, 2,2-[4-(4-aminophenoxyphenyl)][4-(3-aminophenoxyphenyl)]-1,1,1,3,3,3-hexafluoropropane, 1,3-bis(3-aminophenoxy)benzene, 1,4-bis(3-aminophenoxy)benzene, 1,4-bis(4-aminophenoxy)benzene, 1,3-bis(4-aminophenoxy)benzene, 4,4′-bis(4-aminophenoxy)biphenyl, 4,4′-bis(3-aminophenoxy)biphenyl, bis[4-(3-aminophenoxy)phenyl]ketone, bis[4-(4-aminophenoxy)phenyl]ketone, bis[4-(3-aminophenoxy)phenyl]ether, bis[4-(4-aminophenoxy)phenyl]ether, polytetramethylene oxide di-P-aminobenzoate, poly(tetramethylene-3-methyltetramethylene ether)glycol bis(4-aminobenzoate), trimethylene-bis(4-aminobenzoate), p-phenylene-Bis(4-aminobenzoate), m-phenylene-Bis(4-aminobenzoate), bisphenol A-bis(4-aminobenzoate), 2,4-diaminobenzoic acid, 2,5-diaminobenzoic acid, 3,5-diaminobenzoic acid, 3,3′-diamino-4,4′-dicarboxybiphenyl, 4,4′-diamino-3,3′-dicarboxybiphenyl, 4,4′-diamino-2,2′-dicarboxybiphenyl, [bis(4-amino-2-carboxy)phenyl]methane, [bis(4-amino-3-carboxy)phenyl]methane, [bis(3-amino-4-carboxy)phenyl]methane, [bis(3-amino-5-carboxy)phenyl]methane, 2,2-bis[3-amino-4-carboxyphenyl]propane, 2,2-bis[4-amino-3-carboxyphenyl]propane, 2,2-bis[3-amino-4-carboxyphenyl]hexafluoropropane, 2,2-bis[4-amino-3-carboxyphenyl]hexafluoropropane, 3,3′-diamino-4,4′-dicarboxydiphenyl ether, 4,4′-diamino-3,3′-dicarboxydiphenyl ether, 4,4′-diamino-2,2′-dicarboxydiphenyl ether, 3,3′-diamino-4,4′-dicarboxydiphenyl sulfone, 4,4′-diamino-3,3′-dicarboxydiphenyl sulfone, 4,4′-diamino-2,2′-dicarboxydiphenyl sulfone, 2,3-diaminophenol, 2,4-diaminophenol, 2,5-diaminophenol, and 3,5-diaminophenol; hydroxybiphenyl compounds such as 3,3′-diamino-4,4′-dihydroxybiphenyl, 4,4′-diamino-3,3′-dihydroxybiphenyl, 4,4′-diamino-2,2′-dihydroxybiphenyl, and 4,4′-diamino-2,2′,5,5′-tetrahydroxybiphenyl; dihydroxydiphenylmethanes such as 3,3′-diamino-4,4′-dihydroxydiphenylmethane, 4,4′-diamino-3,3′-dihydroxydiphenylmethane, and 4,4′-diamino-2,2′-dihydroxydiphenylmethane; bis[hydroxyphenyl]propanes such as 2,2-bis[3-amino-4-hydroxyphenyl]propane, and 2,2-bis[4-amino-3-hydroxyphenyl]propane; bis[hydroxyphenyl]hexafluoropropanes such as 2,2-bis[3-amino-4-hydroxyphenyl]hexafluoropropane, and 2,2-bis[3-amino-4-hydroxyphenyl]hexafluoropropane; hydroxydiphenyl ethers such as 3,3′-diamino-4,4′-dihydroxydiphenyl ether, 4,4′-diamino-3,3′-dihydroxydiphenyl ether, and 4,4′-diamino-2,2′-dihydroxydiphenyl ether; dihydroxy diphenyl sulfones such as 3,3′-diamino-4,4′-dihydroxy diphenyl sulfone, 4,4′-diamino-3,3′-dihydroxy diphenyl sulfone, and 4,4′-diamino-2,2′-dihydroxy diphenyl sulfone; dihydroxy diphenyl sulfides such as 3,3′-diamino-4,4′-dihydroxy diphenyl sulfide, 4,4′-diamino-3,3′-dihydroxy diphenyl sulfide, and 4,4′-diamino-2,2′-dihydroxy diphenyl sulfide; dihydroxy diphenyl sulfoxides such as 3,3′-diamino-4,4′-dihydroxy diphenyl sulfoxide, 4,4′-diamino-3,3′-dihydroxy diphenyl sulfoxide, and 4,4′-diamino-2,2′-dihydroxy diphenyl sulfoxide; bis[(hydroxyphenyl)phenyl]alkane compounds such as 2,2-bis[4-(4-amino-3-hydroxyphenoxy)phenyl]propane; bis(hydroxyphenoxy)biphenyl compounds such as 4,4′-bis(4-amino-3-hydroxyphenoxy)biphenyl, bis[(hydroxyphenoxy)phenyl]sulfone compounds such as 2,2-bis[4-(4-amino-3-hydroxyphenoxy)phenyl]sulfone; and bis(hydroxyphenoxy)biphenyl compounds such as 4,4′-diamino-3,3′-dihydroxydiphenylmethane, 4,4′-diamino-2,2′-dihydroxydiphenylmethane, 2,2-bis[3-amino-4-carboxyphenyl]propane, and 4,4′-bis(4-amino-3-hydroxyphenoxy)biphenyl. These compounds can be used solely, or two or more types thereof can be used in combination.

The diamino compounds that are particularly suitably used for the polyimide precursor composition of the present invention, particularly suitable for the photosensitive resin composition, are aromatic diamines such as m-phenylenediamine, bis(3-aminophenyl)sulfone, bis(4-aminophenyl)sulfone, 3,3′-diaminodiphenylmethane, bis[4-(3-aminophenoxy)phenyl]sulfone, bis[4-(3-aminophenoxy)phenyl]methane, 2,2-bis[4-(4-aminophenoxy)phenyl]propane, 1,3-bis(3-aminophenoxy)benzene, 1,4-bis(3-aminophenoxy)benzene, 1,4-bis(4-aminophenoxy)benzene, and 1,3-bis(4-aminophenoxy)benzene. Use of the foregoing aromatic diamines is preferable since thermal resistance of an obtained cured film improves.

Moreover, an isocyanate compound used as component (B) is a compound which includes two or more isocyanate groups.

The following are exemplifications of diisocyanates that are usable as the isocyanate compounds: aromatic diisocyanates such as tolylene diisocyanate, xylylene diisocyanate, diphenylmethane diisocyanate, polymeric diphenylmethane diisocyanate, naphthalene diisocyanate, tolidine diisocyanate, and tetramethylxylene diisocyanate; alicyclic diisocyanates such as hydrogenated diphenylmethane diisocyanate, hydrogenated xylylene diisocyanate, isophorone diisocyanate, and norbornene diisocyanate; and aliphatic diisocyanates such as hexamethylene diisocyanate, trimethylhexamethylene diisocyanate, and lysine diisocyanate. Moreover, compounds in which the foregoing diisocyanates are stabilized with a blocking agent such as alcohol, phenol, oxime or the like can also be used as the isocyanate compound. The compounds may be used solely, or two or more types thereof can be used in combination.

As the component (B), the diamino compound and the isocyanate compound can be used solely, or the two can be used in combination.

In the present invention, the diamino compound and/or the isocyanate compound is preferably added in such amounts satisfying that (a)/((b)+(c))=not less than 0.80 but not more than 1.20, where:

(a) is a molar quantity of tetracarboxylic acid dianhydride in the component (A) in the polyimide precursor composition;

(b) is a molar quantity of terminal isocyanate compound in the component (A) in the polyimide precursor composition; and

(c) is a molar quantity of diamino compound and/or isocyanate compound in the component (B) in the polyimide precursor composition.

With the amount contained of the diamino compound and/or isocyanate compound (B) in the foregoing range, imidization reaction of the polyimide precursor composition and the photosensitive resin composition or thermosetting resin composition that use the polyimide precursor composition easily advances, thereby obtaining a polyimide resin of a high polymer weight. This improves thermal resistance, and therefore is preferable.

(II) Photosensitive Resin Composition

One example of using the polyimide precursor composition of the present invention is a photosensitive resin composition. Therefore, the present invention also includes a photosensitive resin composition that uses the polyimide precursor composition. The following description specifically explains a photosensitive resin composition in accordance with the present invention. Needless to say, examples of using the polyimide precursor composition of the present invention are not limited to this example.

A photosensitive resin composition of the present invention is sufficient as long as at least the polyimide precursor composition, a (C) photosensitive resin, and a (D) photopolymerization initiator are included. Provided that the polyimide precursor composition to be used for the photosensitive resin composition of the present invention is the foregoing polyimide precursor composition, any polyimide precursor composition can be used, with no particular limitation thereto.

Namely, a photosensitive resin composition of the present invention is sufficient as long as it includes a (A) urethane imide oligomer having a terminal carboxylic acid group, a (B) diamino compound and/or isocyanate compound, a (C) photosensitive resin, and (D) a photopolymerization initiator.

In the photosensitive resin composition, it is preferable to use a urethane imide oligomer having a terminal tetracarboxylic acid group as the (A) urethane imide oligomer having a terminal carboxylic acid group, which urethane imide oligomer having a terminal tetracarboxylic acid group is obtained by use of polycarbonate diol. However, the (A) urethane imide oligomer is not limited to this.

Moreover, the photosensitive resin composition of the present invention can further include a (E) thermosetting resin, in addition to the (A) urethane imide oligomer having a terminal carboxylic acid group, the (B) diamino compound and/or isocyanate compound, the (C) photosensitive resin, and the (D) photopolymerization initiator.

Since component (A) and component (B) are as described in the foregoing (I), descriptions thereof are omitted here. The following description deals with the (C) photosensitive resin, the (D) photopolymerization initiator, the (E) thermosetting resin, any other components, and methods of how (A) to (D) or (A) to (E) are mixed together.

<(C) Photosensitive Resin>

The (C) photosensitive resin according to the present invention is a resin in which a chemical bond is formed by use of a photopolymerization initiator. Of such resins, the resin preferably is one that has at least one unsaturated double bond inside a molecule. Furthermore, the unsaturated double bond is preferably an acrylic group (CH₂═CH— group), a metacryloyl group (CH═C(CH₃)— group), or a vinyl group (—CH═CH— group).

Examples of the (C) photosensitive resin that are preferably used encompass, however are not limited to: EO-denatured (n=2 to 50) bisphenol F diacrylate, EO-denatured (n=2 to 50) bisphenol A diacrylate, EO-denatured (n=2 to 50) bisphenol S diacrylate, EO-denatured (n=2 to 50) bisphenol F dimethacrylate, EO-denatured (n=2 to 50) bisphenol A dimethacrylate, EO-denatured (n=2 to 50) bisphenol S dimethacrylate, 1,6-hexanediol diacrylate, neopentyl glycol diacrylate, ethylene glycol diacrylate, pentaerythritol diacrylate, trimethylolpropane triacrylate, pentaerythritol triacrylate, dipentaerythritol hexaacyrlate, tetramethylolpropane tetraacrylate, tetraethylene glycol diacrylate, 1,6-hexanediol dimethacrylate, neopentyl glycol dimethacrylate, ethylene glycol dimethacrylate, pentaerysthritol dimethacrylate, trimethylolpropane trimethacrylate, pen taeri thritol trimethacrylate, dipentaerythritol hexamethacrylate, tetramethylolpropane tetramethacrylate, tetraethylene glycol dimethacrylate, methoxy diethylene glycol methacrylate, methoxy polyethylene glycol methacrylate, β-methacryloyloxyethyl hydrogen phthalate, β-methacryloyloxyethyl hydrogen succinate, 3-chloro-2-hydroxypropyl methacrylate, stearyl methacrylate, phenoxyethyl acrylate, phenoxydiethylene glycol acrylate, phenoxypolyethylene glycol acrylate, β-acryloyloxyethyl hydrogen succinate, lauryl acrylate, ethylene glycol dimethacrylate, diethylene glycol dimethacrylate, triethylene glycol dimethacrylate, polyethylene glycol dimethacrylate, 1,3-butylene glycol dimethacrylate, 1,6-hexanediol dimethacrylate, neopentyl glycol dimethacrylate, polypropylene glycol dimethacrylate, 2-hydroxy-1,3-dimethacryloxypropane, 2,2-bis[4-(methacryloxyethoxy)phenyl]propane, 2,2-bis[4-(methacryloxy diethoxy)phenyl]propane, 2,2-bis[4-(methacryloxy polyethoxy)phenyl]propane, polyethylene glycol diacrylate, tripropylene glycol diacrylate, polypropylene glycol diacrylate, 2,2-bis[4-(acryloxy diethoxy)phenyl]propane, 2,2-bis[4-(acryloxy polyethoxy)phenyl]propane, 2-hydroxy-1-acryloxy-3-methacryloxypropane, trimethylolpropane trimethacrylate, tetramethylolmethane triacrylate, tetramethylolmethane tetraacrylate, methoxydipropylene glycol methacrylate, methoxytriethylene glycol acrylate, nonylphenoxy polyethylene glycol acrylate, nonylphenoxy polypropylene glycol acrylate, 1-acryloyloxypropyl-2-phthalate, isostearyl acrylate, polyoxyethylene alkyl ether acrylate, nonylphenoxy ethylene glycol acrylate, polypropylene glycol dimethacrylate, 1,4-butanediol dimethacrylate, 3-methyl-1,5-pentanediol dimethacrylate, 1,6-mexanediol dimethacrylate, 1,9-nonanediol methacrylate, 2,4-diethyl-1,5-pentanediol dimethacrylate, 1,4-cyclohexane dimethanol dimethacrylate, dipropylene glycol diacrylate, tricyclodecane dimethanol deacrylate, hydrogenated 2,2-bis[4-(acryloxy polyethoxy)phenyl]propane, 2,2-bis[4-(acryloxy polypropoxy)phenyl]propane, 2,4-diethyl-1,5-pentanediol diacrylate, ethoxylated trimethylolpropane triacrylate, propoxylated trimethylolpropane triacrylate, isocyanuric acid tri(ethane acrylate), pentaerythritol tetraacrylate, ethoxylated pentaerythritol tetraacrylate, propoxylated pentaerythritol tetraacrylate, ditrimethylolpropane tetraacrylate, dipentaerythritol polyacrylate, isocyanuric acid triallyl ester, glycidyl methacrylate, allyl glycidyl ether, 1,3,5-triacryloylhexahydro-s-triazine, triallyl 1,3,5-benzenecarboxylate, triallylamine, triallyl citrate, triallyl phosphate, allobarbital, diallylamine, diallyl dimethyl silane, diallyl disulfide, diallyl ether, diallyl cyanurate, diallyl isophthalate, diallyl terephthalate, 1,3-diallyloxy-2-propanol, diallyl sulfide diallyl maleate, 4,4′-isopropylidene diphenol dimethacrylate, and 4,4′-isopropylidene diphenol diacrylate. Particularly, it is preferable to use a photosensitive resin in which a repeating unit of EO (ethylene oxide) included in one molecule of a diacrylate or a methacrylate is in a range of 2 to 50, further preferably in a range of 2 to 40. By using such a photosensitive resin which includes a repeating unit of EO in a range of 2 to 50 improves solubility of the photosensitive resin composition in a water-based developing solution whose one typical example is an alkaline aqueous solution. As a result, the amount of time required for development is shortened. Further, stress hardly remains in the cured film obtained by curing the photosensitive resin composition. Hence, for example, especially in case where the cured film is employed in such a manner that it is laminated on a flexible printed wiring board in which its substrate is made from a polyimide resin, the use of such a cured film can avoid curling of the flexible printed wiring board.

Particularly, in view of improving developing properties, it is preferable to use the EO-denatured diacrylate or a dimethacrylate, and further an acrylic resin which includes three or more acrylic or methacrylic groups. Examples of the acrylic resin that are suitably used encompass: ethoxylated isocyanuric acid EO-denatured triacrylate, ethxoylated isocyanuric acid EO-denatured trimethacrylate, ethoxylated trimethylolpropane triacrylate, ethoxylated trimethylolpropane triacrylate, ethoxylated trimethylolpropane triacrylate, trimethylolpropane triacrylate, propoxylated trimethylolpropane triacrylate, pentaerythritol triacrylate, ethoxylated pentaerythritol tetraacrylate, ethoxylated pentaerythritol tetraacrylate, ditrimethylolpropane tetraacrylate, ditrimethylolpropane tetraacrylate, propoxylated pentaerythritol tetraacrylate, pentaerythritol tetraacrylate, dipentaerythritol hexaacrylate, 2,2,2-trisacryloyloxymethylethyl succinic acid, 2,2,2-trisacryloyloxymethylethyl phthalic acid, propoxylated ditrimethylolpropane tetraacrylate, propoxylated dipentaerythritol hexaacrylate, ethoxylated isocyanuric acid triacrylate, ε-caprolactone denatured tris-(2-acryloxyethyl)isocyanurate, caprolactone denatured ditrimethylolpropane tetraacrylate, a compound represented by the following general formula (8):

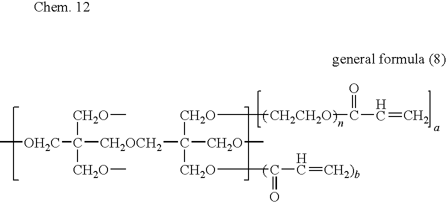

where a+b=6, and n=12, a compound represented by the following general formula (9):

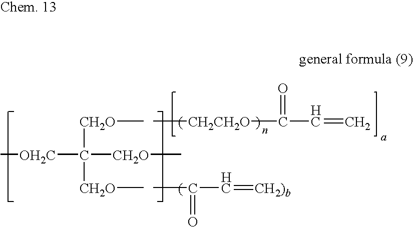

where a+b=4, and n=4, a compound represented by the following general formula (10):

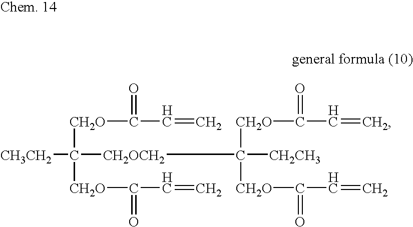

a compound represented by the following general formula (11):

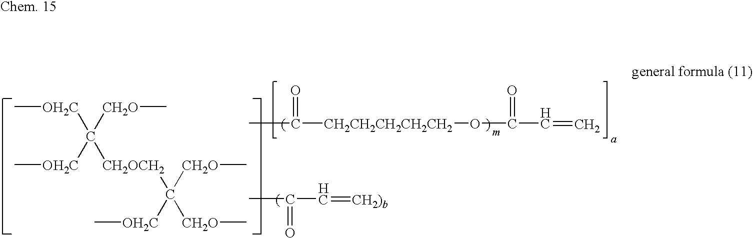

where m=1, a=2, and b=4; or m=1, a=3, and b=3; or m=1, a=6, b=0; or m=2, a=6, b=0, a compound represented by the following general formula (12):

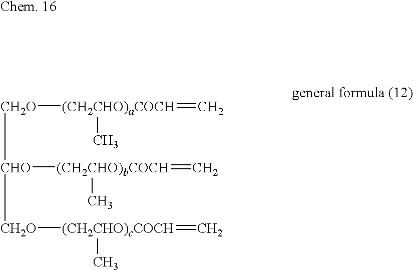

where a+b+c=3.6, a compound represented by the following general formula (13):

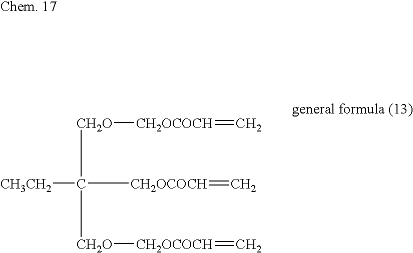

and a compound represented by the following general formula (14):

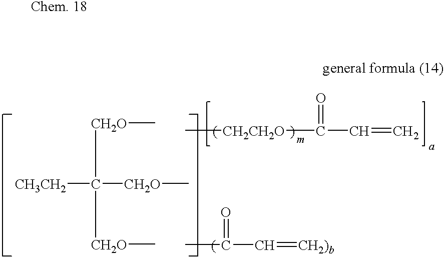

where m·a=3 and a+b=3; “m·a” denotes a product of m and a.

Moreover, acrylic resins in which a hydroxyl group and a carbonyl group are included in a molecular structure skeleton of 2-hydroxy-3-phenoxypropyl acrylate, phthalic acid monohydroxyethyl acrylate, ω-carboxy-polycaprolactone monoacrylate, acrylic acid dimer, pentaerysthritol tri- and tetra-acrylate or the like, can also be suitably used.

Other than the foregoing, a photosensitive resin such as epoxy-denatured acrylic (methacrylic) resin, urethane-denatured acrylic (methacrylic) resin, polyester-denatured acrylic (methacrylic) resin or the like can also be used.

Although just one type of the photosensitive resin can be used, it is preferable to use two or more types in combination to improve thermal resistance of the cured film that has been photo-cured.

<(D) Photopolymerization Initiator>

Examples of a (D) photopolymerization initiator encompass: Michler's ketone, 4,4′-bis(diethylamino)benzophenone, 4,4′,4″-tris(dimethylamino)triphenylmethane, 2,2′-bis(2-chlorophenyl)-4,4′,5,5′-tetraphenyl-1,2′diimidazole, acetophenone, benzoin, 2-methyl benzoin, benzoin methyl ether, benzoin ethyl ether, benzoin isopropyl ether, benzoin isobutyl ether, 2-t-butyl anthraquinone, 1,2-benzo-9,10-anthraquinone, methyl anthraquinone, thioxanthone, 2,4-diethylthioxanthone, 2-isopropylthioxanthone, 1-hydroxycyclohexyl phenyl ketone, diacetyl benzyl, benzyl dimethyl ketal, benzyl diethyl ketal, 2 (2′-furanyl ethylidene)-4,6-bis(trichloromethyl)-S-triazine, 2[2′(5″-methylfuranyl)ethylidene]-4,6-bis(trichloromethyl)-S-triazine, 2(p-methoxyphenyl)-4,6-bis(trichloromethyl)-S-triazine, 2,6-di(p-azidobenzal)-4-methyl cyclohexanone, 4,4′-diazidocalcon, di(tetraalkyl ammonium)-4,4′-diazidostilbene-2,2′-disulfonate, 2,2-dimethoxy-1,2-diphenylethane-1-on, 1-hydroxy-cyclohexyl-phenyl-ketone, 2-hydroxy-2-methyl-1-phenyl-propane-1-on, 1-[4-(2-hydroxyethoxy)-phenyl]-2-hydroxy-2-methyl-1-propane-1-on, 2-methyl-1-[4-(methylthio)phenyl]-2-morpholinopropane-1-on, 2-benzyl-2-dimethylamino-1-(4-morpholinophenyl)-butane-1, bis(2,4,6-trimethylbenzoil)-phenylphosphine oxide, bis(2,6-dimethoxybenzoil)-2,4,4-trimethyl-pentylphosphine oxide, 2,4,6-trimethylbenzoil-diphenyl-phosphine oxide, 2-hydroxy-2-methyl-1-phenyl-propane-1-ketone, bis(n5-2,4-cyclopentadiene-1-yl)-bis(2,6-difluoro-3-(1H-pyrrole-1-yl)-phenyl) titanium, 1,2-octanone dione, 1-[4-(phenylthio)-2-(O-benzoyloxime)], iodonium, (4-methylphenyl)[4-(2-methyl propyl)phenyl]-hexafluorophosphate(1-), ethyl-4-dimethylaminobenzoate, 2-ethylhexyl-4-dimethylaminobenzoate, ethanone, and 1-[9-ethyl-6-(2-methylbenzoil)-9H-carbazole-3-yl]-, 1-(O-acetyl oxyom). The photopolymerization initiator is preferably selected as appropriate, and is preferable to use by mixing one or more types thereof.

The component (A), component (B), component (C) and component (D) in the photosensitive resin composition of the present invention are preferably included so that the component (C) is in a range of 10 to 200 parts by weight and the component (D) is in a range of 0.1 to 50 parts by weight, with respect to a total solid content of the component (A) and the component (B) being 100 parts by weight.

By including the components as such, it is possible to improve various properties (electrical insulating reliability and the like) of a cured product and an insulating film that are ultimately obtained.

If the (C) photosensitive resin is included less than the foregoing range, thermal resistance decreases of a cured coating film attained after photo-curing the photosensitive resin composition, and contrast is not easily obtained when the photosensitive resin composition is exposed to light and developed. Therefore, such an amount of the (C) photosensitive resin may not be preferred. By including the photosensitive resin so as to be in the foregoing range, it is possible to attain a resolution in an optimum range upon exposure to light and development.

If the (D) photopolymerization initiator is less than the foregoing range, there are cases where curing reaction of the acrylic resin upon irradiation of light becomes difficult to occur, thereby causing frequent insufficient curing. On the other hand, if the photosensitive resin composition includes too much of the (D) photopolymerization initiator, adjustment of the amount of light for irradiation becomes difficult, and there may be the case where too much light is irradiated. Therefore, in order to efficiently proceed with the photo-curing reaction, it is preferable to adjust the amount of the (D) photopolymerization initiator to be in the foregoing range.

<(E) Thermosetting Resin>

Examples of the thermosetting resin used for the photosensitive resin composition of the present invention encompass: thermosetting resin such as epoxy resin, isocyanate resin, block isocyanate resin, bismaleimide resin, bisallylnadiimide resin, acrylic resin, methacrylic resin, curable hydrosilyl resin, curable allyl resin, and unsaturated polyester resin; and thermosetting polymers having a reactive group such as an allyl group, a vinyl group, an alkoxysilyl group, or a hydrosilyl group provided on a side chain or a terminal of its polymer chain. Just one type of the foregoing thermosetting components, that is, the (E) thermosetting resin, or two or more types thereof can be used in combination as appropriate.

Among these thermosetting resins, epoxy resin is more preferably used as the (E) thermosetting resin. By including an epoxy resin component, thermal resistance can be provided to a cured film thus obtained by curing the photosensitive resin composition, and further adds adhesiveness to allow adhesion to a conductor such as metal foil, and a circuit board.

Examples of the epoxy resin are epoxy resins that contain at least two epoxy groups in a molecule, which such examples encompass: bisphenol A type epoxy resin, bisphenol AD type epoxy resin, bisphenol S type epoxy resin, bisphenol F type epoxy resin, bisphenol A novolac-type epoxy resin, hydrogenated bisphenol A type epoxy resin, ethylene oxide added bisphenol A type epoxy resin, propylene oxide added bisphenol A type epoxy resin, novolac type epoxy resin, glycidyl ester type epoxy resin, biphenyl type epoxy resin, phenol novolac type epoxy resin, alkylphenol novolac type epoxy resin, polyglycol type epoxy resin, cycloaliphatic epoxy resin, cyclopentadiene type epoxy resin, dicyclopentadiene type epoxy resin, cresol novolac type epoxy resin, glycidylamine type epoxy resin, naphthalene type epoxy resin, urethane-denatured epoxy resin, rubber-denatured epoxy resin, and epoxy-denatured polysiloxane. Just one of the epoxy resins can be used, or two or more types thereof can be used in combination in an arbitrary proportion.

Examples of the epoxy resin encompass: naphthalene tetra-functional type epoxy resin under product name EPICLON HP-4700, cyclopentadiene type epoxy resin under product name EPICLON HP-7200, phenol novolac type epoxy resin under product name EPICLON N-740, epoxy resin having a high thermal resistance under product name EPICLON EXA-7240, cresol novolac type multi-functional epoxy resins under product names EPICLON N-660, N-665, N-670, N-680, N-655-EXP, tetraphenylethane type epoxy resin under product name EPICLON ETePE, and triphenylmethane type epoxy resin under product name EPICLON ETrPM, each of which is manufactured by Dainippon Ink and Chemicals; bisphenol. A type epoxy resin under product name EPICOAT 828 and the like manufactured by Japan Epoxy Resins Co., Ltd.; bisphenol F type epoxy resin under product name YDF-170 and the like manufactured by Tohto Kasei Co., Ltd.; product name EPICOAT 152 and 154 manufactured by Japan Epoxy Resins Co., Ltd.; product name EPPN-201 manufactured by Nippon Kayaku Co., Ltd.; phenol novolac type epoxy resin under product name DEN-438 and the like manufactured by The Dow Chemical Company; o-cresol novolac type epoxy resins under product names EOCN-125S, 103S, 104S and the like, manufactured by Nippon Kayaku Co., Ltd.; product name Epon 1031S manufactured by Japan Epoxy Resins Co., Ltd.; product name Araldite 0163 manufactured by CIBA specialty chemicals Inc., multifunctional epoxy resins under product names DENACOL EX-611, EX-614, EX-614B, EX-622, EX-512, EX-521, EX₄₂₁, EX-411, EX-321 and the like manufactured by Nagase chemicals Co, Ltd.; product name EPICOAT 604 manufactured by Japan Epoxy Resins Co., Ltd.; product name YH434 manufactured by Tohto Kasei Co., Ltd.; product names TETRAD-X and TERRAD-C, manufactured by Mitsubishi Gas Chemical Company, Inc.; product name GAN manufactured by Nippon Kayaku Co., Ltd.; amine type epoxy resin under product name ELM-120 and the like manufactured by Sumitomo Chemical Co., Ltd.; heterocycle-contained epoxy resin under product name Araldite PT810 and the like manufactured by CIBA specialty chemicals Inc.; and cycloaliphatic epoxy resin under product names ERL 4234, 4299, 4221, 4206 and the like manufactured by UCC. The epoxy resin can be used solely, or two or more types thereof can be used in combination.

The thermosetting resin used for the photosensitive resin composition of the present invention can also be an epoxy compound that has just one epoxy group in one molecule, for example n-butyl glycidyl ether, phenyl glycidyl ether, dibromophenyl glycidyl ether, or dibromocresyl glycidyl ether. Moreover, the thermosetting resin can be used together with a cycloaliphatic epoxy compound such as 3,4-epoxycyclohexyl, or methyl(3,4-epoxycyclohexane)carboxylate.

Of these epoxy resins, it is particularly preferable to use an epoxy resin that includes two or more epoxy groups in one molecule, in view of improvement in thermal resistance, solvent resistance, chemical resistance, and moisture vapor resistance of the photosensitive resin composition.

With the photosensitive resin composition of the present invention, the following compounds can be used together, as a curing agent of the photosensitive resin: for example, phenolic resins such as phenol novolac type phenolic resin, cresol novolac type phenolic resin, and naphthalene type phenolic resin; amino resins; urea resins; melamine resins; dicyandiamide; dihydrazine compounds; imidazole compounds; a Lewis acid; Broensted acid salts; polymercaptan compounds; and isocyanate and block isocyanate compounds.

An amount used of the thermosetting resin in the photosensitive resin component of the present invention is preferably in a range of 0.5 to 100 parts by weight with respect to a total solid content of the (A) urethane imide oligomer having a terminal carboxylic acid group, the (B) diamino compound and/or isocyanate compound, the (C) photosensitive resin, and the (D) photopolymerization initiator being 100 parts by weight. It is particularly preferable that the thermosetting resin is in a range of 1.0 to 50 parts by weight. It is preferable to include the thermosetting resin in the foregoing range since thermal resistance, chemical resistance, and electrical insulating reliability of the cured film made by the photosensitive resin component improves.

Moreover, the photosensitive resin component of the present invention can also use a curing accelerator together with the thermosetting resin. The curing accelerator is not particularly limited, and examples thereof encompass: phosphine-based compounds such as triphenylphosphine; amine-based compounds such as tertiary amines, trimethanolamine, triethanolamine, and tetraethanolamine; borate-based compounds such as 1,8-diaza-bicyclo[5,4,0]-7-undecenium tetraphenylborate; imidazoles such as imidazole, 2-ethyl imidazole, 2-ethyl-4-methyl imidazole, 2-phenyl imidazole, 2-undecyl imidazole, 1-benzyl-2-methyl imidazole, 2-heptadecylimidazole, 2-isopropyl imidazole, and 2,4-dimethyl imidazole, 2-phenyl-4-methyl imidazole; imidazolines such as 2-methyl imidazoline, 2-ethyl imidazoline, 2-isopropyl imidazoline, 2-phenyl imidazoline, 2-undecylimidazoline, 2,4-dimethyl imidazoline, and 2-phenyl-4-methyl imidazoline; and azine-based imidazoles such as 2,4-diamino-6-[2′-methylimidazolyl-(1′)]-ethyl-s-triazine, 2,4-diamino-6-[2′-undecylimidazolyl-(1′]-ethyl-s-triazine, and 2,4-diamino-6-[2′-ethyl-4′-methyl imidazolyl-(1′)]-ethyl-s-triazine. Among the curing accelerators, it is preferable to use the imidazoles such as 2-ethyl-4-methylimidazole, 2-phenyl-4-methylimidazole, 2,4-diamino-6-[2′-undecylimidazolyl-(1′)]-ethyl-s-triazine, since these curing accelerators give excellent storage stability of the photosensitive resin component.

<Other Components>

The photosensitive resin component of the present invention can further include various additives if necessary, such as a filler, an adhesive auxiliary agent, an antifoaming agent, a leveling agent, a flame retardant, a coloring agent, or a polymerization inhibitor. The photosensitive resin component can include, as the filler, fine inorganic filler such as silica, mica, talc, barium sulfate, wollastonite, and calcium carbonate, or fine organic polymer filler. The photosensitive resin component can include, as the antifoaming agent, for example, a silicon-based compound or an acrylic-based compound. Moreover, as the leveling agent, a silicon-based compound, an acrylic-based compound, or like compounds can be included. Further, the photosensitive resin component can include, as the flame retardant, a phosphoric ester-based compound, a halogen-based compound, a metal hydroxide, an organophosphate-based compound, or the like. Moreover, as the coloring agent, for example a phthalocyanine-based compound, an azo-based compound, carbon black, or titanium oxide can be included therein. A silane coupling agent, a triazole-based compound, a tetrazole-based compound, a triazine-based compound or the like can be included as the adhesive auxiliary agent (also referred to as an adhesive additive). Moreover, the photosensitive resin component can include, for example, hydroquinone, hydroquinone monomethyl ether or the like as the polymerization inhibitor. The various additives can be used solely, or two or more additives can be used in combination. Moreover, it is preferable to determine an amount to be contained of the additive as appropriate.

<Method for Mixing (A) to (D) or (A) to (E)>

A photosensitive resin composition of the present invention is attained by evenly mixing each of the components (A) to (D) or (A) to (E), and any of the foregoing other components if necessary. It is not particularly limited in how to evenly mix each of the components, and the components can be mixed, for example, by using a general mixing device such as a three-roll or beads mill device. When a solution has a low viscosity, the compounds can be mixed by use of a general stirring device.

(III) Thermosetting Resin Composition

Another example of using the polyimide precursor composition of the present invention is a thermosetting resin composition. Hence, a thermosetting resin composition which uses the polyimide precursor composition is also included in the present invention. Needless to say, use of the polyimide precursor composition is not limited to this example.

A thermosetting resin composition of the present invention is sufficient as long as at least the polyimide precursor composition and a (E) thermosetting resin is included. As long as the polyimide precursor composition used for the thermosetting resin composition of the present invention is the foregoing polyimide precursor composition, there are no other limitations thereto and any polyimide precursor composition is usable.

Namely, the photosensitive resin composition of the invention of the present application is sufficient as long as it includes a (A) urethane imide oligomer having a terminal carboxylic acid group, a (B) diamino compound and/or isocyanate compound, and a (E) thermosetting resin.

In the photosensitive resin composition, a urethane imide oligomer having a terminal tetracarboxylic acid group, which is obtained by use of polycarbonate diol, is preferably used as the (A) urethane imide oligomer having a terminal carboxylic acid group. However, it is not limited to this.

Moreover, the photosensitive resin composition of the present invention may further include other component(s), in addition to the (A) urethane imide oligomer having a terminal carboxylic acid group, the (B) diamino compound and/or isocyanate compound, and the (E) thermosetting resin.

The components (A) and (B) are identical to ones described in the foregoing (I), therefore descriptions thereof are omitted here. Components exemplified in the foregoing (II) are suitably used as the (E) thermosetting resin and also as the other components.

The components (A), (B) and (E) in the thermosetting resin composition of the present invention are preferably included so that the component (E) is included in a range of 0.5 to 100 parts by weight with respect to a total solid content of the components (A) and (B) being 100 parts by weight.

It is preferable to include the component (E) as such, since various properties (e.g., electrical insulating reliability) of a cured product and an insulating film thus ultimately obtained improves.

If the (E) thermosetting resin exceeded the foregoing range, this might obstruct the curing reaction of the polyimide precursor, thereby causing insufficient mechanical strength. Therefore, it is preferable to prepare the thermosetting resin composition so as to be in the foregoing range, in order to efficiently proceed with the curing reaction.

<Method for Mixing (A), (B), and (E)>

The thermosetting resin composition of the present invention is obtained by evenly mixing each of the components (A), (B), and (E), and any other components if necessary. The components can be evenly mixed by use of, for example, a general mixing device such as a three-roll or a beads mill device. Moreover, in a case where viscosity of a solution is low, the components can be mixed by use of a general stirring device.

(IV) Polyimide Precursor Composition Solution

A polyimide precursor composition solution obtained by dissolving, to an organic solvent, the polyimide precursor composition, the photosensitive resin composition, or the thermosetting resin composition, is also included in the present invention. The polyimide precursor composition, the photosensitive resin composition, and the thermosetting resin composition have high solubility in various organic solutions, and for example, the following solvents are usable: sulfoxide-based solvents such as dimethyl sulfoxide and diethyl sulfoxide; formamide-based solvents such as N,N-dimethyl formamide and N,N-diethyl formamide; acetamide-based solvents such as N,N-dimethylacetamide and N,N-diethylacetamide; pyrrolidone-based solvents such as N-methyl-2-pyrrolidone and N-vinyl-2-pyrrolidone; phenolic solvents such as phenol, o-, m-, or p-cresol, xylenol, halogenated phenol, and catechol; or, symmetrical glycol diethers such as hexamethyl phosphoramide, γ-butyrolactone, methyl monoglyme (1,2-dimethoxyethane), methyl diglyme (bis(2-methoxyethyl)ether), methyl triglyme (1,2-bis(2-methoxyethoxy)ethane), methyl tetraglyme (bis[2-(2-methoxyethyl)]ether), ethyl monoglyme (1,2-diethoxyethane), ethyl diglyme (bis(2-ethoxyethyl)ether, and butyl diglyme (bis(2-butoxyethyl)ether); acetates such as γ-butyrolactone, N-methyl-2-pyrrolidone, methyl acetate, ethyl acetate, isopropyl acetate, n-propyl acetate, butyl acetate, propylene glycol monomethyl ether acetate, ethylene glycol monobutyl ether acetate, diethylene glycol monoethyl ether acetate (another name: Carbitol acetate, 2-(2-butoxyethoxy)ether acetate), diethylene glycol monobutyl ether acetate, 3-methoxybutyl acetate, ethylene glycol monomethyl ether acetate, ethylene glycol monoethyl ether acetate, dipropylene glycol methyl ether acetate, propylene glycol diacetate, and 1,3-butylene glycol diacetate; ethers such as dipropylene glycol methyl ether, tripropylene glycol methyl ether, propylene glycol n-propyl ether, dipropylene glycol n-propylether, propylene glycol n-butyl ether, dipropylene n-butyl ether, tripylene glycol n-propyl ether, propylene glycol phenyl ether, dipropylene glycol dimethyl ether, 1,3-dioxolane, ethylene glycol monobutyl ether, diethylene glycol monoethyl ether, diethylene glycol monobutyl ether, and ethylene glycol monoethyl ether. As the foregoing solvent, hexane, acetone, toluene, xylene or the like, each of which has a low boiling point, may be used together if necessary.

Among the solvents, particularly the symmetric glycol diethers are preferable, since the polyimide precursor composition, the photosensitive resin composition, and the thermosetting resin composition are highly soluble in such a solvent.

The polyimide precursor composition solution prepared by dissolving the polyimide precursor composition of the present invention in an organic solvent preferably includes not less than 10 parts by weight but not more than 100 parts by weight of the organic solvent with respect to a total solid content of the component (A) and component (B) being 100 parts by weight.

The polyimide precursor composition solution prepared by dissolving the photosensitive resin composition of the present invention in the organic solvent preferably includes not less than 10 parts by weight but not more than 100 parts by weight of the organic solvent with respect to a total solid content of the components (A), (B), (C), and (D), and (E) if necessary, being 100 parts by weight.

The polyimide precursor composition solution prepared by dissolving the thermosetting resin composition of the present invention in an organic solvent preferably includes not less than 10 parts by weight but not less than 100 parts by weight of the organic solvent with respect to a total solid content of the components (A), (B), and (E) being 100 parts by weight.

Having a polyimide precursor composition solution in the foregoing range is preferable, because it allows a decrease in film shrinking ratio caused by drying.

(V) Method for Use of Polyimide Precursor Composition

By directly using the polyimide precursor composition, photosensitive resin composition, or thermosetting resin composition, or after preparation of the polyimide precursor composition solution, a cured film or a pattern is formable as described below. First, the polyimide precursor composition, the photosensitive resin composition, or the thermosetting resin composition is applied to a substrate. Alternatively, the polyimide precursor composition solution is applied to a substrate, thereafter dried so as to remove the organic solvent. Application to the substrate can be carried out by screen printing, curtain rolling, reverse rolling, spray coating, rotational application by use of a spinner, or the like. An applied film (preferable thickness: 5 μm to 100 μm, particularly 10 μm to 100 is dried at a temperature of not higher than 120° C., preferably in a range of 40° C. to 100° C.

When the photosensitive resin composition is used, after drying the applied film, a negative photomask is placed thereon, and active light such as ultraviolet ray, visible light, electron beam or the like is irradiated to the dried applied film. Next, a portion that is not exposed to light is washed with a developing solution by use of various methods such as use of a shower, a puddle, soaking, or ultrasonic waves, so that a relief pattern is provided. Since the time required for the pattern to be exposed differs depending on (i) spray pressure and flow speed of the developing device and (ii) a temperature of an etchant, it is preferable to find an optimum condition for the device as appropriate.

It is preferable to use an alkaline aqueous solution as the developing solution. The developing solution may include a water-soluble organic solvent such as methanol, ethanol, n-propanol, isopropanol, or N-methyl-2-pyrrolidone. Examples of an alkaline compound to attain the alkaline aqueous solution encompass hydroxides, carbonates, hydrogencarbonates, or amine compounds of, for example, alkaline metals, alkaline earth metals, or ammonium ion.

More specifically, examples of the alkaline compound encompass: sodium hydroxide, potassium hydroxide, ammonium hydroxide, sodium carbonate, potassium carbonate, ammonium carbonate, sodium hydrogencarbonate, potassium hydrogencarbonate, ammonium hydrogencarbonate, tetramethylammonium hydroxide, tetraethylammonium hydroxide, tetrapropylammonium hydroxide, tetraisopropylammonium hydroxide, N-methyldiethanolamine, N-ethyldiethanolamine, N,N-dimethylethanolamine, triethanolamine, triisopropanolamine, and triisopropylamine, and any other compound is obviously usable as long as the aqueous solution exhibits basicity. A concentration of the alkaline compound that is suitably used in a developing step of the photosensitive resin composition of the present invention is in a range of 0.01% to 20% by weight, and is particularly preferably in a range of 0.02° A to 10% by weight. A temperature of the developing solution depends on a constitution of the photosensitive resin composition or the constitution of the alkaline developing solution, but is generally preferably used in a range of not less than 0° C. to not more than 80° C., more generally in a range of not less than 10° C. to not more than 60° C.

From the relief pattern formed in the developing step, excess remaining parts are removed by rinsing the pattern. Water, acidic aqueous solution or the like may be used as the rinsing fluid.

Next, heat is applied to (i) the film obtained by applying on a substrate the polyimide precursor composition, the thermosetting resin composition, or the polyimide precursor composition solution including the composition, and thereafter drying the applied composition or solution, or (ii) the relief pattern obtained by applying on a substrate the photosensitive resin composition or a polyimide precursor composition solution including the photosensitive resin composition and thereafter exposing this to light and developing this applied composition or solution. Imidization of a urethane imide oligomer having a terminal carboxylic acid group with a diamino compound and/or isocyanate compound via a heating process allows obtainment of a cured film having excellent thermal resistance. Thickness of the cured film is determined in view of a wiring thickness or the like, however is preferably in a thickness of approximately 2 μm to 50 μm. It is preferable to have a low ultimate curing temperature, with which imidization can be carried out with a low heating temperature, so as to prevent oxidation of wiring or the like and to prevent a decrease in adhesion of the wiring and the base material.

The imidization temperature at this time is preferably in a range of not less than 100° C. but not more than 250° C., further preferably not less than 120° C. but not more than 200° C., and is particularly preferably not less than 130° C. but not more than 190° C. It is not preferable to have a high ultimate heating temperature, since such a high temperature causes deterioration of the wiring due to oxidation thereof.

A cured film made of the polyimide precursor composition, the photosensitive resin composition, or the thermosetting resin composition, has excellent thermal resistance, excellent electrical and mechanical properties, and particularly has excellent flexibility.

For example, an insulating film made of a photosensitive resin composition suitably has a film thickness of around 2 μm to 50 μm and a resolution power of at least 10 μm upon photo-curing, particularly having a resolution power of around 10 μm to 1000 μm. Therefore, the insulating film made of the photosensitive resin composition is particularly suitable as an insulating material of a high-density flexible substrate. Furthermore, the insulating film thus obtained is used as (1) various wiring coating protective agents of a photo-curing type, (ii) a photosensitive thermally-resistant adhesive, (iii) insulating coating of an electric wire and cable, and (iv) the like.

Moreover, for example, an insulating film of the thermosetting resin composition suitably has a film thickness in a range of 2 μm to 50 μm, and has good electrical insulating reliability, water vapor resistance, and flexibility. Therefore, an insulating film obtained from the thermosetting resin composition is particularly suitable as an insulating material of a flexible substrate that requires high flexibility. Furthermore, the thermosetting resin composition is used as (i) various thermosetting-type wiring coating protective agents, (ii) thermally-resistant adhesives, (iii) insulating coatings of electrical code and cable, and (iv) the like.

Note that the present invention can provide a same insulating material even by use of a resin film obtained by applying the polyimide precursor composition solution to a base material surface and thereafter drying the solution thus applied.

### EXAMPLES

The present invention is explained in further details in the following Examples, however the present invention is not limited thereto.

### Example 1

<Synthesis of Urethane Imide Oligomer having Terminal Carboxylic Acid Group>

As a solvent for polymerization, methyl triglyme (17.5 g) was poured into a separable flask under positive nitrogen pressure. To this methyl triglyme, 17.5 g (0.1003 mol) of tolylene diisocyanate (mixture of 80 tolylene-2,4-diisocyanate and 20% tolylene-2,6-diisocyanate) was added, and this mixture was heated to 80° C. so as to dissolve tolylene diisocyanate. Into this mixture, a solution was added for 1 hour, which solution thus added was a solution of (i) and (ii) dissolved in methyl triglyme (50.0 g), which (i) was 40.0 g (0.040 mol) of a polyalkylene dial (product name: PTXG1000 manufactured by Asahi Kasei Co., Ltd., having an average molecular weight of 1000, which product is a polyalkylene diol represented by the following general formula (15):

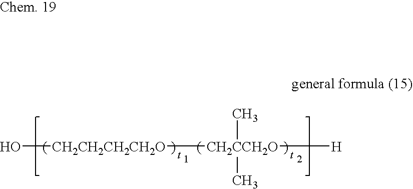

where t₁ and t₂ denote an integer of not less than 1), and (ii) was 10.0 g (0.01 mol) of a polycarbonate diol (product name PCDL T5651 manufactured by Asahi Kasei Co., Ltd., having an average molecular weight of 1000, which product is a polycarbonate diol represented by the following general formula (16):

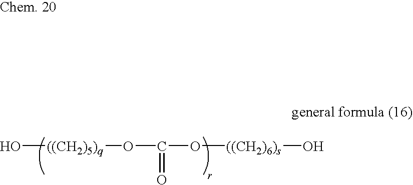

where q, r, and s denote integers of not less than 1). This obtained a further solution, which was then heated to reflux for 5 hours. The reactant solution is referred to as intermediate A.

To another reaction apparatus different from the reaction apparatus used in the foregoing reaction, 52.0 g (0.100 mol) of 2,2-bis[4-(3,4-dicarboxyphenoxy)phenyl]propane dianhydride (hereinafter referred to as BPADA) and methyl triglyme (52.0 g) were added. This mixture was heated to 80° C., and BPADA was dispersed in methyl triglyme.

The intermediate A was added to this solution over 1 hour, so as to react with the solution. After the intermediate A was added, the solution was heated to 180° C., and the solution was reacted with the intermediate A for 5 hours. As a result of this reaction, a solution of a urethane imide oligomer having a terminal acid anhydride was obtained. To this solution, 7.20 g (0.400 mol) of pure water was added, and further the solution was heated to reflux at 80° C. for 5 hours, so as to obtain a solution of a urethane imide oligomer having a terminal carboxylic acid group.

<Preparation of Polyimide Precursor Composition Solution>

The obtained solution of a urethane imide oligomer having a terminal carboxylic acid group was cooled to room temperature, and 11.69 g (0.040 mol) of 1,3-bis(aminophenoxy)benzene was added thereto. This mixture was evenly stirred at room temperature for 1 hour, thereby obtaining a polyimide precursor composition solution. The obtained solution had a solute concentration of 52% and a viscosity of 250 poise at 23° C.

<Evaluation of Storage Stability of Polyimide Precursor Composition Solution>

In order to confirm storage stability of the polyimide precursor composition solution, the polyimide precursor composition solution was sealed in a screw tube of 10 ml and left to stand in that state for 1 month in a room kept at a temperature of 20° C. After elapse of 1 month, viscosity of the solution was measured. The viscosity measured 250 poise at 23° C., thereby demonstrating that no change in viscosity had occurred. Thus, it was made clear that the polyimide precursor composition solution is storable at room temperature for a long term.

<Production of Cured Film on Polyimide Film>

The polyimide precursor composition solution was flow-cast and applied to a polyimide film having a thickness of 75 μm (product name: 75NPI, manufactured by Kaneka Corporation) so that an ultimately dried film thickness becomes 25 μm, by using a Baker's applicator. This applied solution was dried at 80° C. for 20 minutes, so as to form a resin film of the present invention on a polyimide film that serves as a base. The resin film thus obtained was heated at 160° C. for 90 minutes under an air atmosphere so as to imidize the resin film, which obtained a cured film. Thus, a polyimide film laminate in which a cured film is formed on a polyimide film that serves as a base was produced.

<Evaluation of Cured Film>

The obtained cured film was evaluated for the following items. Results of the evaluations are as shown in Table 1.

(i) Adhesiveness of Cured Film

Evaluation of adhesive strength of the obtained cured film was carried out by a cross-cut tape method based on JIS K5400.

Cured films that showed no peel-off in the cross-cut tape method was evaluated as “good” and marked with a circle on Table 1;
cured films in which more than half of film pieces in matrix were remained was evaluated as “moderate” and marked with a triangle; and
cured films in which less than half of film pieces in matrix were remained was evaluated as “poor” and marked with a cross.

(ii) Environmental Test Stability of Cured Film

If the cured film is insufficiently imidized, stability of the cured film inside an environmental test device decreases.

For this reason, stability of the cured film inside an environmental test device was measured. With use of a thermo-hygrostat Type: PR-1K, manufactured by ESPEC Corp. as the environmental test device, a cured film was evaluated, which was formed on a polyimide film. The cured film was evaluated after the cured film was subjected to an environment of a 85° C./85% RH for 1000 hours.

Results which exhibited no change in the polyimide resin of the cured film was evaluated as “good” marked with a circle; results in which the polyimide resin of the cured film partially dissolved was evaluated as “moderate” and marked with a triangle; and
results in which the polyimide resin of the cured film completely dissolved was evaluated as “poor” and marked with a cross.

(iii) Chemical Resistance

Evaluation of chemical resistance was carried out to a surface of the curing film. The evaluation was carried out under evaluation conditions of items 1 to 3 as below, by observing a state of the surface of the cured film after soaking the polyimide film into certain chemical solutions.

Evaluation item 1: after soaking the cured film in isopropanol at 25° C. for 10 minutes, the cured film was air-dried.
Evaluation item 2: After soaking the cured film in 2N hydrochloric acid solution at 25° C. for 10 minutes, the cured film was washed with pure water and then air-dried.
Evaluation item 3: After soaking the cured film in 2N sodium hydroxide solution at 25° C. for 10 minutes, the cured film was washed with pure water and then air-dried.
Results exhibiting no change to the polyimide resin of the cured film was evaluated as “good” marked with a circle;
results in which a part of the polyimide resin of the cured film dissolved was evaluated as “moderate” and marked with a triangle; and
results in which the polyimide resin of the cured film completely dissolved was evaluated as “poor” and marked with a cross.

(iv) Flexibility Evaluation

A polyimide resin solution was applied on a polyimide film having a thickness of 25 μm (Apical 25NPI, manufactured by Kaneka Corporation) to obtain an ultimate film thickness of a cured film of 25 μm. This applied solution was dried at 80° C. for 20 minutes, then at 160° C. for 90 minutes to obtain a polyimide film laminate. The polyimide film laminate was cut out to strips of 30 mm×10 mm, and the strip was bent by 180° for 10 times at a 15 mm point, and thereafter was evaluated by visually inspecting the applied film whether or not a crack generated.

A circle in Table 1 denotes that no crack generated in the cured film;

a triangle denotes that a slight crack generated in the cured film; and

a cross denotes that a crack generated in the cured film.

<v> Wettability

Wettability of the cured film produced in <Production of Cured Resin on Polyimide Film> was measured based on a JIS K6768 measuring method.

TABLE 1

| | | Ex. 1 | Ex. 2 | Ex. 3 | Ex. 4 | Ex. 5 | Ex. 6 |
|---|---|---|---|---|---|---|---|
| Adhesiveness of Applied Film | | ◯ | ◯ | ◯ | ◯ | ◯ | ◯ |
| Environmental Test Stability | | ◯ | ◯ | ◯ | ◯ | ◯ | ◯ |
| of Film | | | | | | | |
| Chemical | Item 1 | ◯ | ◯ | ◯ | ◯ | ◯ | ◯ |
| Resistance | Item 2 | ◯ | ◯ | ◯ | ◯ | ◯ | ◯ |
| | Item 3 | ◯ | ◯ | ◯ | ◯ | ◯ | ◯ |

| | | | | | | |
|---|---|---|---|---|---|---|
| Flexibility Evaluation | ◯ | ◯ | ◯ | ◯ | ◯ | ◯ |
| Wettability (mN/m) | 38 | 38 | 38 | 36 | 38 | 38 |

### Example 2

<Synthesis of Urethane Imide Oligomer Having Terminal Carboxylic Acid Group>

As a solvent for polymerization, methyl triglyme (17.5 g) was poured into a separable flask under positive nitrogen pressure. To this methyl triglyme, 17.5 g (0.1003 mol) of tolylene diisocyanate (mixture of 80% tolylene-2,4-diisocyanate and 20% tolylene-2,6-diisocyanate) was added, and this mixture was heated to 80° C. so as to dissolve tolylene diisocyanate. Into this solution, a solution was added for 1 hour, which solution thus added was a solution of 50.0 g (0.050 mol) of a polyalkylene diol (product name: PTXG1000 manufactured by Asahi Kasei Co., Ltd.; having an average molecular weight of 1000, which product is a polyalkylene diol represented by the general formula (15)) dissolved in methyl triglyme (50.0 g). This obtained a further solution, which was then heated to reflux for 5 hours. The reactant solution is referred to as intermediate B.

To another reaction apparatus different from the reaction apparatus used in the foregoing reaction, 52.0 g (0.100 mol) of 2,2-bis[4-(3,4-dicarboxyphenoxy)phenyl]propane dianhydride (hereinafter referred to as BPADA) and methyl triglyme (52.0 g) were added. This mixture was heated to 80° C., and BPADA was dispersed in methyl triglyme.

The intermediate B was added to this solution over 1 hour, so as to react with the solution. After the intermediate B was added, the solution was heated to 180° C., and the solution was reacted with the intermediate B for 5 hours. As a result of this reaction, a solution of a urethane imide oligomer having a terminal acid anhydride was obtained. To this solution, 7.20 g (0.400 mol) of pure water was added, and further the solution was heated to reflux at 80° C. for 5 hours, so as to obtain a solution of a urethane imide oligomer having a terminal carboxylic acid group.

<Preparation of Polyimide Precursor Composition Solution>

The obtained solution of a urethane imide oligomer having a terminal carboxylic acid group was cooled to room temperature, and 11.69 g (0.040 mol) of 1,3-bis(aminophenoxy)benzene was added thereto. This mixture was evenly stirred at room temperature for 1 hour, thereby obtaining a polyimide precursor composition solution.

The obtained solution had a solute concentration of 52% and a viscosity of 210 poise at 23° C.

<Evaluation of Storage Stability of Polyimide Precursor Composition Solution>

In order to confirm storage stability of the polyimide precursor composition solution, the polyimide precursor composition solution was sealed in a screw tube of 10 ml and left to stand in that state for 1 month in a room kept at a temperature of 20° C. After elapse of 1 month, viscosity of the solution was measured. The viscosity measured 210 poise at 23° C., thereby demonstrating that no change in viscosity had occurred. Thus, it was made clear that the polyimide precursor composition solution is storable at room temperature for a long term.

Furthermore, a cured film prepared from the polyimide precursor composition was evaluated in the same method as Example 1. Results of the evaluations are as shown in Table 1.

### Example 3

<Synthesis of Urethane Imide Oligomer having Terminal Carboxylic Acid Group>

As a solvent for polymerization, methyl triglyme (17.5 g) was poured into a separable flask under positive nitrogen pressure. To this methyl triglyme, 17.5 g (0.1003 mol) of tolylene diisocyanate (mixture of 80% tolylene-2,4-diisocyanate and 20% tolylene-2,6-diisocyanate) was added, and this mixture was heated to 80° C. so as to dissolve tolylene diisocyanate. Into this solution, a solution was added for 1 hour, which solution thus added was a solution of 90.0 g (0.050 mol) of a polyalkylene diol (product name: PTXG1800 manufactured by Asahi Kasei Co., Ltd., having an average molecular weight of 1800, which product is a polyalkylene dial represented by the general formula (15)) dissolved in methyl triglyme (90.0 g). This obtained a further solution, which was then heated to reflux for 5 hours. The reactant solution is referred to as intermediate C.

To another reaction apparatus different from the reaction apparatus used in the foregoing reaction, 52.0 g (0.100 mol) of 2,2-bis[4-(3,4-dicarboxyphenoxy)phenyl]propane dianhydride (hereinafter referred to as BPADA) and methyl triglyme (52.0 g) were added This mixture was heated to 80° C., and BPADA was dispersed in methyl triglyme.

The intermediate C was added to this solution over 1 hour, so as to react with the solution. After the intermediate B was added, the solution was heated to 180° C., and the solution was reacted with the intermediate C for 5 hours. As a result of this reaction, a solution of a urethane imide oligomer having a terminal acid anhydride was obtained. To this solution, 7.20 g (0.400 mol) of pure water was added, and further the solution was heated to reflux at 80° C. for 5 hours, so as to obtain a solution of a urethane imide oligomer having a terminal carboxylic acid group.

<Preparation of Polyimide Precursor Composition Solution>

The obtained solution of a urethane imide oligomer having a terminal carboxylic acid group was cooled to room temperature, and 11.69 g (0.040 mol) of was added thereto. This mixture was evenly stirred at room temperature for 1 hour, thereby obtaining a polyimide precursor composition solution. The obtained solution had a solute concentration of 52%, and a viscosity of 280 poise at 23° C.

<Evaluation of Storage Stability of Polyimide Precursor Composition Solution>

In order to confirm storage stability of the polyimide precursor composition solution, the polyimide precursor composition solution was sealed in a screw tube of 10 ml and left to stand in that state for 1 month in a room kept at a temperature of 20° C. After elapse of 1 month, viscosity of the solution was measured. The viscosity measured 280 poise at 23° C., thereby demonstrating that no change in viscosity had occurred. Thus, it was made clear that the polyimide precursor composition solution is storable at room temperature for a long term.

Furthermore, a cured film obtained by use of the polyimide precursor composition was evaluated in the same method as Example 1. Results of the evaluations are as shown in Table 1.

### Example 4

<Synthesis of Urethane Imide Oligomer Having Terminal Carboxylic Acid Group>

As a solvent for polymerization, methyl triglyme (17.5 g) was poured into a separable flask under positive nitrogen pressure. To this methyl triglyme, 17.5 g (0.1003 mol) of tolylene diisocyanate (mixture of 80 tolylene-2,4-diisocyanate and 20% tolylene-2,6-diisocyanate) was added, and this mixture was heated to 80° C. so as to dissolve tolylene diisocyanate. Into this solution, a solution was added for 1 hour, which solution thus added was a solution of (i) and (ii) dissolved in methyl triglyme (82.0 g), which (i) was 72.0 g (0.040 mol) of a polyalkylene diol (product name: PTXG1800 manufactured by Asahi Kasei Co., Ltd., having an average molecular weight of 1800, which product is a polyalkylene diol represented by the general formula (15)) and (ii) was 10.0 g (0.010 mol) of a polycarbonate diol (product name PCDL T5651 manufactured by Asahi Kasei Co., Ltd., having an average molecular weight of 1000, which product is a polycarbonate diol represented by the general formula (16)). This obtained a further solution, which was then heated to reflux for 5 hours. The reactant solution is referred to as intermediate D.

To another reaction apparatus different from the reaction apparatus used in the foregoing reaction, 26.4 g (0.100 mol) of 5-(2,5-dioxotetrahydro-3-furanyl)-3-methyl-3-cyclohexene-1,2-dicarboxylic anhydride and methyl triglyme (26.4 g) were added. This mixture was heated to 80° C., and 5-(2,5-dioxotetrahydro-3-furanyl)-3-methyl-3-cyclohexene-1,2-dicarboxylic anhydride was dispersed in methyl triglyme.

The intermediate D was added to this solution over 1 hour, so as to react with the solution. After the intermediate D was added, the solution was heated to 180° C., and the solution was reacted with the intermediate D for 5 hours. As a result of this reaction, a solution of a urethane imide oligomer having a terminal acid anhydride was obtained. To this solution, 7.20 g (0.400 mol) of pure water was added, and further the solution was heated to reflux at 80° C. for 5 hours, so as to obtain a solution of a urethane imide oligomer having a terminal carboxylic acid group.

<Preparation of Polyimide Precursor Composition Solution>

The obtained solution of a urethane imide oligomer having a terminal carboxylic acid group was cooled to room temperature, and 11.69 g (0.040 mol) of 1,3-bis(aminophenoxy)benzene was added thereto. This mixture was evenly stirred at room temperature for 1 hour, thereby obtaining a polyimide precursor composition solution. The obtained solution had a solute concentration of 51% and a viscosity of 240 poise at 23° C.

<Evaluation of Storage Stability of Polyimide Precursor Composition Solution>

In order to confirm storage stability of the polyimide precursor composition solution, the polyimide precursor composition solution was sealed in a screw tube of 10 ml and left to stand in that state for 1 month in a room kept at a temperature of 20° C. After elapse of 1 month, viscosity of the solution was measured. The viscosity measured 240 poise at 23° C., thereby demonstrating that no change in viscosity had occurred. Thus, it was made clear that the polyimide precursor composition solution is storable at room temperature for a long term.

Furthermore, a cured film obtained by use of the polyimide precursor composition was evaluated in the same method as Example 1. Results of the evaluations are as shown in Table 1.

### Example 5

<Synthesis of Urethane Imide Oligomer Having Terminal Carboxylic Acid Group>

Water (0.400 mol) that was added to the urethane imide oligomer having a terminal acid anhydride after the synthesis reaction thereof in Example 1 was changed to methanol (0.400 mol, 12.8 g). This half-esterified the terminal of the urethane imide oligomer, so as to obtain a solution of a urethane imide oligomer having a terminal carboxylic acid group.

<Preparation of Polyimide Precursor Composition Solution>

The obtained solution of a urethane imide oligomer having a terminal carboxylic acid group was cooled to room temperature, and 11.69 g (0.040 mol) of 1,3-bis(aminophenoxy)benzene was added thereto. This mixture was evenly stirred at room temperature for 1 hour, thereby obtaining a polyimide precursor composition solution. The obtained solution had a solute concentration of 52% and a viscosity of 260 poise at 23° C.

<Evaluation of Storage Stability of Polyimide Precursor Composition Solution>

In order to confirm storage stability of the polyimide precursor composition solution, the polyimide precursor composition solution was sealed in a screw tube of 10 ml and left to stand in that state for 1 month in a room kept at a temperature of 20° C. After elapse of 1 month, viscosity of the solution was measured. The viscosity measured 260 poise at 23° C., thereby demonstrating that no change in viscosity had occurred. Thus, it was made clear that the polyimide precursor composition solution is storable at room temperature for a long term.

Furthermore, a cured film obtained by use of the polyimide precursor composition was evaluated in the same method as Example 1. Results of the evaluations are as shown in Table 1.

### Example 6

### Preparation of Polyimide Precursor Composition Solution

The solution of a urethane imide oligomer having a terminal carboxylic acid group thus obtained in Example 1 was cooled to room temperature, and 46.03 g (0.040 mol) of an isocyanate compound (product name: Takenate B-815N; manufactured by Mitsui Chemicals Polyurethanes, Inc.) was added thereto. This mixture was evenly stirred at room temperature for 1 hour, thereby obtaining a polyimide precursor composition solution. The obtained solution had a solute concentration of 52% and a viscosity of 200 poise at 23° C.

<Evaluation of Storage Stability of Polyimide Precursor Composition Solution>

In order to confirm storage stability of the polyimide precursor composition solution, the polyimide precursor composition solution was sealed in a screw tube of 10 ml and left to stand in that state for 1 month in a room kept at a temperature of 20° C. After elapse of 1 month, viscosity of the solution was measured. The viscosity measured 200 poise at 23° C., thereby demonstrating that no change in viscosity had occurred. Thus, it was made clear that the polyimide precursor composition solution is storable at room temperature for a long term.

Furthermore, a cured film obtained by use of the polyimide precursor composition was evaluated in the same method as Example 1. Results of the evaluations are as shown in Table 1.

### Comparative Example 1

First, 2.73 g (23.5 mmol) of hexamethylenediamine was dissolved into 24.0 g of dimethylacetamide. Into this mixture, 3.78 g (11.75 mmol) of 3,3′,4,4′-benzophenone tetracarboxylic acid dianhydride was gradually added for 30 minutes, thereby obtaining an oligomer having a polyamide bond. After evenly stirring the oligomer for 1 hour, 3.02 g (9.40 mmol) of 3,3′,4,4′-benzophenone tetracarboxylic acid was added thereto, and the mixture was further stirred for 1 hour. As a result, a viscous solution was obtained (solute concentration of 28% by weight). The solution thus obtained measured a viscosity of 3100 poise.

In order to confirm storage stability of the obtained solution, the obtained solution was sealed in a screw tube of 10 ml and left to stand in that state for 1 month in a room kept at a temperature of 20° C. After elapse of 1 month, viscosity of the solution was measured. The viscosity measured 300 poise at 23° C., thereby demonstrating a remarkable change in viscosity. Thus, it was made clear that there was a problem with the storage stability.

A cured film produced by use of the obtained solution was evaluated in the same method as Example 1. Results of the evaluations are as shown in Table 2.

TABLE 2

| | | Com- | Com- | Com- | Com- |
|---|---|---|---|---|---|
| | | parative | parative | parative | parative |
| | | Example 1 | Example 2 | Example 3 | Example 4 |
| Adhesiveness of Applied | | X | ◯ | ◯ | ◯ |
| Film | | | | | |
| Environmental Test | | X | X | ◯ | ◯ |
| Stability of Film | | | | | |
| Chemical | Item 1 | X | Δ | X | X |
| Resistance | Item 2 | X | X | X | X |
| | Item 3 | X | Δ | X | X |

| | | | | |
|---|---|---|---|---|
| Flexibility Evaluation | X | ◯ | X | X |
| Wettability (mN/m) | 34 | Not more | 34 | Not more |
| | | than 30 | | than 30 |

### Comparative Example 2

First, 200 g (0.384 mol) of 2,2-bis[4-(3,4-dicarboxyphenoxy)phenyl]propane dianhydride was dispersed into 183 g of 1,2-bis(2-methoxyethoxy)ethane, and its temperature was kept at 80° C. Further to this, 128 g (0.154 mol) of a silicon diamine (siloxane diamine) (product name: KF8010, manufactured by Shin-Etsu Chemical Co., Ltd. having a molecular weight of 830, which product is a silicon diamine of the following general formula (17):

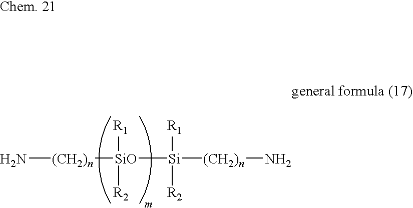

where each R₁ and R₂ independently denote a methyl group; n=3; and m=6 to 11,
was added to the mixture and evenly stirred for 30 minutes. Next, this mixture was heated to 140° C. and stirred for 1 hour. After the reaction terminated, the mixture was heated to 180° C. to reflux for 3 hours. After termination of this reaction, the mixture was cooled to room temperature, and 49.3 g (1.54 mol) of methanol was added to the mixture. This mixture was evenly stirred for 30 minutes, thereafter was heated to 80° C. to reflux for 3 hours. This obtained an imide solution having a half-esterified terminal carboxylic acid. This solution was thereafter cooled to room temperature, and 99.7 g (0.230 mol) of bis[4-(3-aminophenoxy)phenyl]sulfone was added to the solution. This solution was evenly stirred at room temperature for 1 hour, thereby obtaining a polyimide precursor composition solution. The obtained solution had a solute concentration of 70% by weight and a viscosity of 120 poise at 23° C.

In order to confirm storage stability of the polyimide precursor composition solution, the polyimide precursor composition solution was sealed in a screw tube of 10 ml and left to stand in that state for 1 month in a room kept at a temperature of 20° C. After elapse of 1 month, viscosity of the solution was measured. The viscosity measured 120 poise at 23° C., thereby demonstrating that no change in viscosity had occurred. Thus, it was made clear that the polyimide precursor composition solution is storable at room temperature for a long term.

A cured film produced by use of the obtained solution was evaluated in the same method as the evaluations carried out in Example 1. Results of the evaluations are as shown in Table 2.

As shown in Table 2, the results made it clear that the cured film obtained in the present Comparative Example had poor environmental test stability, and also poor solvent resistance and poor alkaline resistance.

### Comparative Example 3

First, 8.22 g (41.1 mmol) of 4,4′-diaminodiphenyl ether was dissolved into 55.0 g of N,N-dimethylacetamide, and the mixture was stirred at room temperature. Further to the mixture, 11.9 g (54.8 mmol) of a pyromellitic acid dianhydride was added, and then this mixture was stirred at room temperature for 2 hours. Thereafter, 1.32 g (41.1 mmol) of methanol and 0.066 g of dimethylaminoethanol were added to the mixture, and the mixture was stirred for 2 hours while being heated by use of a hot water bath at 70° C. The mixture was thereafter cooled to room temperature, and 2.74 g (13.7 mmol) of 4,4′-diaminodiphenyl ether was added thereto. The mixture was further stirred for 1 hour, which ultimately obtained an even solution. A viscosity of the obtained solution was 18 poise at 23° C.

In order to confirm storage stability of the obtained solution, the obtained solution was sealed in a screw tube of 10 ml and left to stand in that state for 1 month in a room kept at a temperature of 20° C. After elapse of 1 month, viscosity of the solution was measured. The viscosity measured 50 poise at 23° C.; thus, this result made it clear that there was a problem with the storage stability at room temperature.

A cured film produced by use of the obtained solution was evaluated in the same method as Example 1. Results of the evaluations are as shown in Table 2.

### Comparative Example 4

As a solvent for polymerization, methyl triglyme (17.5 g) was poured into a separable flask under positive nitrogen pressure. To this methyl triglyme, 17.5 g (0.1003 mol) of tolylene diisocyanate (mixture of 80 tolylene-2,4-diisocyanate and 20% tolylene-2,6-diisocyanate) was added, and this mixture was heated to 80° C. so as to dissolve tolylene diisocyanate. Into this solution, a solution was added for 1 hour, which solution thus added was a solution of (i) and (ii) dissolved in methyl triglyme (50.0 g), which (i) was 40.0 g (0.040 mol) of a polyalkylene diol (product name: PTXG1000 manufactured by Asahi Kasei Co., Ltd., having an average molecular weight of 1000, which product is a polyalkylene diol represented by the following general formula (15)), and (ii) was 10.0 g (0.01 mol) of a polycarbonate diol (product name PCDL T5651 manufactured by Asahi Kasei Co., Ltd., having an average molecular weight of 1000, which product is a polycarbonate diol represented by the following general formula (16)). This obtained a further solution, which was then heated to reflux for 5 hours. The reactant solution is referred to as intermediate A.

To another reaction apparatus different from the reaction apparatus used in the foregoing reaction, 52.0 g (0.100 mol) of 2,2-bis[4-(3,4-dicarboxyphenoxy)phenyl]propane dianhydride (hereinafter referred to as BPADA) and methyl triglyme (52.0 g) were added. This mixture was heated to 80° C., and SPADA was dispersed in methyl triglyme.

The intermediate A was added to this solution over 1 hour, so as to react with the solution. After the intermediate A was added, the solution was heated to 180° C., and the solution was reacted with the intermediate A for 5 hours. As a result of this reaction, a solution of a urethane imide oligomer having a terminal acid anhydride was obtained. To this solution, 7.20 g (0.400 mol) of pure water was added, and further the solution was heated to reflux at 80° C. for 5 hours, so as to obtain a solution of a urethane imide oligomer having a terminal carboxylic acid group.

Evaluations were carried out in the same method as Example 1, to a cured film produced by use of the foregoing solution of a urethane imide oligomer having a terminal carboxylic acid group, which solution does not include a diamino compound and/or an isocyanate compound. Results thereof are as shown in Table 2.

### Comparative Example 5

First, 7.00 g (32.1 mmol) of a pyromellitic acid dianhydride was dispersed into 31.3 g of 1,2-bis(2-methoxyethoxy)ethane, and further 2.31 g of water was added thereto. This mixture was stirred at 80° C. for 10 hours, so as to obtain a pyromellitic acid solution. Into this solution, 6.43 g (32.1 mmol) of 4,4-diaminodiphenyl ether was added, so as to prepare a solution.

Formation of a film was attempted by use of this solution in the same method as the evaluation method of Example 1, however the solution solidified on the surface of the polyimide film, and a film could not be formed.

### Comparative Example 6

First, 200 g (0.384 mol) of 2,2-bis[4-(3,4-dicarboxyphenoxy)phenyl]propane dianhydride was dispersed into 183 g of 1,2-bis(2-methoxyethoxy)ethane, while this mixture was kept at 80° C. Thereafter, 128 g (0.154 mol) of silicon diamine (siloxane diamine) (product name: KF8010, manufactured by Shin-Etsu Chemical Co., Ltd.; molecular weight: 830, which product is a silicon diamine of the general formula (7)) was added into the mixture, then the mixture was evenly stirred for 30 minutes. Next, the mixture was heated to 140° C. and stirred for 1 hour. After the reaction terminated, the mixture was heated to 180° C. to reflux for 3 hours. The mixture was cooled to room temperature, and 99.7 g (0.230 mol) of bis[4-(3-aminophenoxy)phenyl]sulfone was added into the mixture and evenly stirred at room temperature for 1 hour, thereby obtaining a polyimide precursor composition solution. Note that no water was added. The obtained solution had a solute concentration of 70% by weight and a viscosity of not less than 10000 poise at 23° C., which was thus turned out to be an elastic material with a high viscosity. Even if this solution was diluted so that the solute concentration became 20% by weight, the solution still had an extremely high viscosity of 6000 poise at 23° C. Thus, the obtained solution was one which was impossible to evaluate its physical properties.

### Synthesis Example 1

As a solvent for polymerization, methyl triglyme (17.5 g) was poured into a separable flask under positive nitrogen pressure. To this methyl triglyme, 17.5 g (0.1003 mol) of tolylene diisocyanate (mixture of 80% tolylene-2,4-diisocyanate and 20% tolylene-2,6-diisocyanate) was added, and this mixture was heated to 80° C. so as to dissolve tolylene diisocyanate. Into this solution, a solution was added for 1 hour, which solution thus added was a solution of (i) and (ii) dissolved in methyl triglyme (50.0 g), which (i) was 40.0 g (0.040 mol) of a polyalkylene diol (product name: PTXG1000 manufactured by Asahi Kasei Co., Ltd., having an average molecular weight of 1000, which product is a polyalkylene diol represented by the following general formula (15):

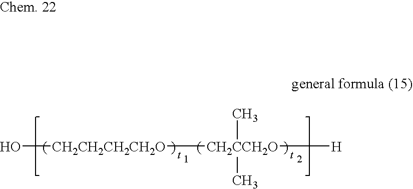

where t₁ and t₂ denote an integer of not less than 1), and) was 10.0 g (0.01 mol) of a polycarbonate diol (product name PCDL T5651 manufactured by Asahi Kasei Co., Ltd., having an average molecular weight of 1000, which product is a polycarbonate diol represented by the following general formula (16):

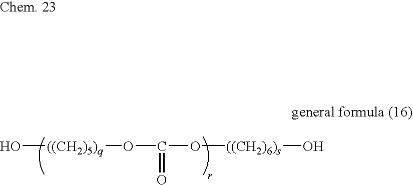

where q, r, and s denote integers of not less than 1). This obtained a further solution, which was then heated to reflux for 5 hours. The reactant solution is referred to as intermediate A.

To another reaction apparatus different from the reaction apparatus used in the foregoing reaction, 52.0 g (0.100 mol) of 2,2-bis[4-(3,4-dicarboxyphenoxy)phenyl]propane dianhydride (hereinafter referred to as BPADA) and methyl triglyme (52.0 g) were added. This mixture was heated to 80° C. and BPADA was dispersed in methyl triglyme.

The intermediate A was added to this solution over 1 hour, so as to react with the solution. After the intermediate A was added, the solution was heated to 180° C., and the solution was reacted with the intermediate A for 5 hours. As a result of this reaction, a solution of a urethane imide oligomer having a terminal acid anhydride was obtained. To this solution, 7.20 g (0.400 mol) of pure water was added, and further the solution was heated to reflux at 80° C. for 5 hours, so as to obtain a solution of a urethane imide oligomer having a terminal carboxylic acid group. This synthetic resin is referred to as resin A.

### Synthesis Example 2

As a solvent for polymerization, methyl triglyme (17.5 g) was poured into a separable flask under positive nitrogen pressure. To this methyl triglyme, 17.5 g (0.1003 mol) of tolylene diisocyanate (mixture of 80 tolylene-2,4-diisocyanate and 20% tolylene-2,6-diisocyanate) was added, and this mixture was heated to 80° C. so as to dissolve tolylene diisocyanate. Into this solution, a solution was added for 1 hour, which solution thus added was a solution of 50.0 g (0.050 mol) of a polyalkylene diol (product name: PTXG1000 manufactured by Asahi Kasei Co., Ltd., having an average molecular weight of 1000, which product is a polyalkylene diol represented by the general formula (15)) dissolved in methyl triglyme (50.0 g). This obtained a further solution, which was then heated to reflux for 5 hours. The reactant solution is referred to as intermediate B.

To another reaction apparatus different from the reaction apparatus used in the foregoing reaction, 52.0 g (0.100 mol) of 2,2-bis[4-(3,4-dicarboxyphenoxy)phenyl]propane dianhydride (hereinafter referred to as BPADA) and methyl triglyme (52.0 g) were added. This mixture was heated to 80° C., and BPADA was dispersed in methyl triglyme.

The intermediate B was added to this solution over 1 hour, so as to react with the solution. After the intermediate B was added, the solution was heated to 180° C., and the solution was reacted with the intermediate B for 5 hours. As a result of this reaction, a solution of a urethane imide oligomer having a terminal acid anhydride was obtained. To this solution, 7.20 g (0.400 mol) of pure water was added, and further the solution was heated to reflux at 80° C. for 5 hours, so as to obtain a solution of a urethane imide oligomer having a terminal carboxylic acid group. This synthetic resin is referred to as resin B.

### Synthesis Example 3

As a solvent for polymerization, methyl triglyme (17.5 g) was poured into a separable flask under positive nitrogen pressure. To this methyl triglyme, 17.5 g (0.1003 mol) of tolylene diisocyanate (mixture of 80 tolylene-2,4-diisocyanate and 20% tolylene-2,6-diisocyanate) was added, and this mixture was heated to 80° C. so as to dissolve tolylene diisocyanate. Into this solution, a solution was added for 1 hour, which solution thus added was a solution of 90.0 g (0.050 mol) of a polyalkylene diol (product name: PTXG1800 manufactured by Asahi Kasei Co., Ltd., having an average molecular weight of 1800, which product is a polyalkylene diol represented by the general formula (15)) dissolved in methyl triglyme (90.0 g). This obtained a further solution, which was then heated to reflux for 5 hours. The reactant solution is referred to as intermediate C.

To another reaction apparatus different from the reaction apparatus used for the foregoing reaction, 52.0 g (0.100 mol) of 2,2-bis[4-(3,4-dicarboxyphenoxy)phenyl]propane dianhydride (hereinafter referred to as BPADA) and methyl triglyme (52.0 g) were added. This mixture was heated to 80° C., and BPADA was dispersed in methyl triglyme.

The intermediate C was added to this solution over 1 hour, so as to react with the solution. After the intermediate C was added, the solution was heated to 180° C., and the solution was reacted with the intermediate C for 5 hours. As a result of this reaction, a solution of a urethane imide oligomer having a terminal acid anhydride was obtained. To this solution, 7.20 g (0.400 mol) of pure water was added, and further the solution was heated to reflux at 80° C. for 5 hours, so as to obtain a solution of a urethane imide oligomer having a terminal carboxylic acid group. This synthetic resin is referred to as resin C.

### Synthesis Example 4

As a solvent for polymerization, methyl triglyme (17.5 g) was poured into a separable flask under positive nitrogen pressure. To this methyl triglyme, 17.5 g (0.1003 mol) of tolylene diisocyanate (mixture of 80 tolylene-2,4-diisocyanate and 20% tolylene-2,6-diisocyanate) was added, and this mixture was heated to 80° C. so as to dissolve tolylene diisocyanate. Into this solution, a solution was added for 1 hour, which solution thus added was a solution of (i) and (ii) dissolved in methyl triglyme (82.0 g), which (i) was 72.0 g (0.040 mol) of a polyalkylene diol (product name: PTXG1800 manufactured by Asahi Kasei Co., Ltd., having an average molecular weight of 1800, which product is a polyalkylene diol represented by the general formula (15)) and (ii) was 10.0 g (0.010 mol) of a polycarbonate diol (product name PCDL T5651 manufactured by Asahi Kasei Co., Ltd., having an average molecular weight of 1000, which product is a polycarbonate diol represented by the general formula (16)). This obtained a further solution, which was then heated to reflux for 5 hours. The reactant solution is referred to as intermediate D.

To another reaction apparatus different from the reaction apparatus used in the foregoing reaction, 26.4 g (0.100 mol) of 5-(2,5-dioxotetrahydro-3-furanyl)-3-methyl-3-cyclohexene-1,2-dicarboxylic acid anhydride and methyl triglyme (26.4 g) were added. This mixture was heated to 80° C., and 5-(2,5-dioxotetrahydro-3-furanyl)-3-methyl-3-cyclohexene-1,2-dicarboxylic anhydride was dispersed in methyl triglyme.

The intermediate D was added to this solution over 1 hour, so as to react with the solution. After the intermediate D was added, the solution was heated to 180° C., and the solution was reacted with the intermediate D for 5 hours. As a result of this reaction, a solution of a urethane imide oligomer having a terminal acid anhydride was obtained. To this solution, 7.20 g (0.400 mol) of pure water was added, and further the solution was heated to reflux at 80° C. for 5 hours, so as to obtain a urethane imide oligomer having a terminal carboxylic acid group. This synthetic resin is referred to as resin D.

### Synthesis Example 5

Water (0.400 mol) that was added to the urethane imide oligomer having a terminal acid anhydride after the synthesis reaction thereof in Example 1 was changed to methanol (0.400 mol). This half-esterified the terminal of the urethane imide oligomer, so as to obtain a solution of a urethane imide oligomer having a terminal carboxylic acid group. This synthetic resin is referred to as resin E.

### Examples 7 and 8

<Preparation of Polyimide Precursor Composition Solution Including Photosensitive Resin Composition>

To the solution of a urethane imide oligomer having a terminal carboxylic acid group obtained in Synthesis Examples 1 and 2, a diamino compound, a photosensitive resin, a photopolymerization initiator, and an organic solvent were added, so as to produce a photosensitive resin composition. The amounts contained of each of the constituent material with respect to a resin solid content and the types of material are as shown in Table 3. The amount of the solvent 1,2-bis(2-methoxyethoxy)ethane that is the solvent shown in the table is an entire solvent amount including the solvent contained in the synthesis resin solution and the like. In carrying out the following evaluations, bubbles in the mixed solution were completely removed by a bubble-removing device, in advance.

TABLE 3
unit: parts by weight

| | | Ex. 7 | Ex. 8 | Ex. 9 | Ex. 10 | Ex. 11 | Ex. 12 |
|---|---|---|---|---|---|---|---|
| Component (A) | Resin A | 31.0 | — | — | — | — | 31.0 |
| | Resin B | — | 31.0 | — | — | — | — |
| | Resin C | — | — | 32.9 | — | — | — |
| | Resin D | — | — | — | 31.3 | — | — |
| | Resin E | — | — | — | — | 31.0 | — |
| Component (B) | 1,3-bis(3-amino- | 7.6 | 7.6 | 5.7 | 7.3 | 7.6 | — |
| | phenoxy)benzene | | | | | | |
| | B-815N^{<7>} | — | — | — | — | — | 8.9 |
| Component (C) | A-9300^{<1>} | 2.3 | 2.3 | 3.6 | 3.6 | 2.3 | 2.3 |
| | BPE-1300^{<2>} | 17.0 | 17.0 | 17.0 | 17.0 | 17.0 | 17.0 |
| Component (D) | IRGACURE819^{<3>} | 1.9 | 1.9 | 1.9 | 1.9 | 1.9 | 1.9 |
| Component (E) | EPICLON | — | — | 5 | 5 | — | — |
| | N-665^{<5>} | | | | | | |
| Other | Barium sulfate | 28.9 | 28.9 | 28.9 | 28.9 | 28.9 | 28.9 |
| Components | AEROGIL R-974^{<4>} | 2.6 | 2.6 | 2.6 | 2.6 | 2.6 | 2.6 |
| | CR-741^{<6>} | 8.7 | 8.7 | 8.7 | 8.7 | 8.7 | 8.7 |
| | 1,2-bis(2-methoxy- | 100 | 100 | 100 | 100 | 100 | 100 |
| | ethoxy)ethane | | | | | | |
| | Solid content | 50 | 50 | 51 | 51 | 50 | 51 |
| | concentration of | | | | | | |
| | photosensitive | | | | | | |
| | resin composition | | | | | | |
| | solution | | | | | | |

^{<1>}Product Name: NK ESTER A-9300(ethoxylated isocyanuric acid triacrylate), manufactured by Nakamura Chemical Co., Ltd.
^{<2>}Ethoxylated bisphenol A diacrylate, manufactured by Nakamura Chemical Co., Ltd. (molecular weight: 1684)
^{<3>}Photopolymerization Initiator, manufactured by CIBA specialty chemicals Inc.
^{<4>}Silica particules, manufactured by Nippon AEROSIL CO., LTD
^{<5>}Product name of cresol novolac type multifunctional epoxy resin, manufactured by Dainippon Ink and Chemicals
^{<6>}Product name of phosphoric ester-based flame retardant, manufactured by Daihachi Chemical Industry Co., Ltd.
^{<7>}Product name of isocyanulate compound, manufactured by Mitsui Chemicals Polyurethanes, Inc.

<Production of Applied Film on Polyimide Film>

A polyimide precursor composition solution including the photosensitive resin composition was flow-cast and applied to a polyimide film of 75 μm (product name: 75NPI, manufactured by Kaneka Corporation), by using a Baker's applicator, to an area of 100 mm×100 mm, so that an ultimately dried film thickness becomes 25 μm, and the applied composition solution was dried at 80° C. for 20 minutes. Thereafter, a negative photomask having an area of 50 mm×50 mm and a line width/space width ratio of 100 μm/100 μm was disposed to expose the composition solution to 300 mJ/cm² of ultraviolet ray under a nitrogen atmosphere. To this photosensitive film, a spray development was carried out by use of a solution that is a 1.0% by weight sodium carbonate solution heated to 30° C., with a discharge pressure of 1.0 kgf/mm². After the development, the film was sufficiently washed thoroughly with pure water, then heated and dried in an oven at 170° C. for 60 minutes, so as to produce a cured film of a photosensitive resin composition.

<Evaluation of Cured Film>

Evaluations were carried out for the following items of the cured film thus obtained. Results of the evaluations are as shown in Table 4.

TABLE 4

| | Ex. | Ex. | Ex. | Ex. | | | Comparative |
|---|---|---|---|---|---|---|---|
| Evaluated Items | 7 | 8 | 9 | 10 | Ex. 11 | Ex. 12 | Example 7 |
| Photosensitivity | ◯ | ◯ | ◯ | ◯ | ◯ | ◯ | ◯ |
| Adhesiveness | ◯ | ◯ | ◯ | ◯ | ◯ | ◯ | ◯ |
| Flexibility | ◯ | ◯ | ◯ | ◯ | ◯ | ◯ | ◯ |
| Moisture-resistant | ◯ | ◯ | ◯ | ◯ | ◯ | ◯ | X |
| Insulating property | | | | | | | |
| Solder thermal | — | — | ◯ | ◯ | — | — | — |
| resistance | | | | | | | |
| Wettability | 38 | 38 | 38 | 36 | 38 | 38 | Not more |
| (mN/m) | | | | | | | than 30 |

(i) Photosensitivity Evaluation

Evaluation of photosensitivity of the photosensitive resin composition was determined by observing a surface of the cured film obtained in the foregoing <Production of Applied Film on Polyimide Film>.

A circle in Table 4 denotes that a clear light exposure pattern having a line width/space width ratio of 100/100 μm was drawn on the polyimide film surface, without any unstableness in a line caused by a peel-off in a line section and without any undissolved parts in the space section;

a triangle denotes that a clear light exposure pattern having a line width/space width ratio of 100/100 μm was drawn on the polyimide film surface, and although the line is unstable caused by a peel-off in the line section, there are no undissolved parts in the space section; and
a cross denotes that no clear light exposure pattern having a line width/space width ratio of 100/100 μm was drawn on the polyimide film surface, the line section is peeled off, and undissolved parts remain in the space section.

(ii) Adhesiveness of Cured Film

Adhesive strength of the cured film of the photosensitive resin composition obtained in the foregoing <Production of Applied Film on Polyimide Film> was evaluated by a cross-cut tape method based on JIS K5400.

Cured films that showed no peel-off in the cross-cut tape method was evaluated as “good” and marked with a circle in Table 4;
cured films in which not less than 95% of film pieces in matrix were remained was evaluated as “moderate” and marked with a triangle; and
cured films in which less than 80% of film pieces in matrix were remained was evaluated as “poor” and marked with a cross.

(iii) Flexibility

In the same method as the <Production of Applied Film on Polyimide Film>, a cured-film-laminated film in which a cured film made of the photosensitive resin composition is stacked on a surface of a polyimide film having a thickness of 25 μm (Apical 25NPI, manufactured by Kaneka Corporation) was produced. The cured-film-laminated film was cut out to strips of 30 mm×10 mm; the strip was bent 10 times by 180° at a 15 mm point, so as to evaluate by visual inspection whether or not a crack generated on the applied film.

A circle in Table 4 denotes that no crack generated in the cured film;
a triangle denotes that a slight crack generated in the cured film; and
a cross denotes that a crack generated in the cured film.

(iv) Moisture-Resistant Insulating Property

On a flexible copper-clad laminate (thickness of copper foil: 12 μm, polyimide film being Apical 25NPI manufactured by Kaneka Corporation, copper foil adhered to film with polyimide-based adhesive), a comb-shaped pattern having a line width/space width ratio of 100 μm/100 μm was produced. Thereafter, the laminate was soaked in 10% by volume sulfuric acid aqueous solution for 1 minute, then was washed with pure water, which as a result surface processed the copper foil. Thereafter, in the same method as that in <Production of Applied Film on Polyimide Film>, a cured film of the photosensitive resin composition was produced on the comb-shaped pattern, so as to prepare a test strip. In an environmental test machine at 85° C. and at 85% R^{H}, a direct current of 60V was applied to both terminal parts of the test strip, so as to observe any changes in an insulating resistance value and occurrence of a migration.

A circle in Table 4 denotes that a resistance of not less than 10⁶ (10 to the power of 6) in not less than 500 hours after start of the test was exhibited, and which no migration or dendrite occurred; and
a cross denotes that occurrence of migration, dendrite, or the like in not less than 500 hours after start of the test was exhibited.

(v) Wettability

Wettability of a covering film manufactured by producing an applied film on the polyimide film was measured based on the JIS K6768 measuring method.

(vi) Solder Thermal Resistance

A photosensitive resin composition was flow-east and applied to a polyimide film of 75 μm (product name: 75NPI, manufactured by Kaneka Corporation), by using a Baker's applicator, to an area of 100 mm×100 mm, so that an ultimately dried film thickness becomes 25 μm, and the applied composition was dried at 80° C. for 20 minutes. Thereafter, a negative photomask having an area of 50 mm×50 mm and a line width/space width ratio of 100 μm/100 μm was disposed to expose the composition solution to 300 mJ/cm² of ultraviolet ray under a nitrogen atmosphere. To this photosensitive film, a spray development was carried out by use of a solution that is a 1.0% by weight sodium carbonate solution heated to 30° C., with a discharge pressure of 1.0 kgf/mm². After the development, the film was thoroughly washed with pure water, then heated and dried in an oven at 170° C. for 60 minutes, so as to produce a cured film of a photosensitive resin composition.

To a solder bath in which solder is completely melted at 260° C., the applied film was floated so as to have a surface on which the cured film of the photosensitive resin composition was applied in contact with the solder bath, and the applied film was pulled up after 10 seconds. This operation was carried out 3 times, and thereafter, an adhesive strength of the cured film was evaluated by a cross-cut tape method based on JIS K₅₄₀₀:

Cured films that showed no peel-off in the cross-cut tape method were evaluated as “good” and marked with a circle;
cured films in which not less than 95% of film pieces in matrix were remained were evaluated as “moderate” and marked with a triangle; and
cured films in which less than 80% of film pieces in matrix were remained were evaluated as “poor” and marked with a cross.

### Examples 9 and 10

To the solution of a urethane imide oligomer having a terminal carboxylic acid group obtained in Synthesis Examples 3 and 4, a diamino compound, a photosensitive resin, a photopolymerization initiator, an organic solvent, and, as a thermosetting resin composition, epoxy resin (EPICLON N-665, a cresol novolac type multi-functional epoxy resin) were added, so as to produce a photosensitive resin composition. The amounts contained of each of the constituent material with respect to a resin solid content and the types of material are as shown in Table 3. The amount of the solvent 1,2-bis(2-methoxyethoxy)ethane that is the solvent shown in the table is an entire solvent amount including the solvent contained in the synthesis resin solution and the like. Bubbles in the mixed solution were completely removed by a bubble-removing device in advance, and thereafter, the same evaluations as Examples 7 and 8 were carried out. Results of the evaluations are as shown in Table 4.

### Example 11

To the solution of a urethane imide oligomer having a terminal carboxylic acid group thus obtained in Synthesis Example 5 in which its terminal is esterified, a diamino compound, a photosensitive resin, a photopolymerization initiator, and an organic solvent were added so as to produce a photosensitive resin composition. The amounts contained of each of the constituent material with respect to a resin solid content and the types of material are as shown in Table 3. The amount of the solvent 1,2-bis(2-methoxyethoxy)ethane that is the solvent shown in the table is an entire solvent amount including the solvent contained in the synthesis resin solution and the like. Bubbles in the mixed solution were completely removed by a bubble-removing device in advance, and thereafter, the same evaluations as Examples 7 and 8 were carried out. Results of the evaluations are as shown in Table 4.

### Example 12

To the solution of a urethane imide oligomer having a terminal carboxylic acid group thus obtained by Synthesis Example 1, an isocyanate compound, a photosensitive resin, a photopolymerization initiator, and an organic solvent were added so as to produce a photosensitive resin composition. The amounts contained of each of the constituent material with respect to a resin solid content and the types of material are as shown in Table 3. The amount of the solvent 1,2-bis(2-methoxyethoxy)ethane that is the solvent shown in the table is an entire solvent amount including the solvent contained in the synthesis resin solution and the like. Bubbles in the mixed solution were completely removed by a bubble-removing device in advance, and thereafter, the same evaluations as Examples 7 and 8 were carried out. Results of the evaluations are as shown in Table 4.

### Synthesis Example 6

As a solvent for polymerization, methyl triglyme (17.5 g) was poured into a separable flask under positive nitrogen pressure. To this methyl triglyme, 17.5 g (0.1003 mol) of tolylene diisocyanate (mixture of 80 tolylene-2,4-diisocyanate and 20% tolylene-2,6-diisocyanate) was added, and this mixture was heated to 80° C. so as to dissolve tolylene diisocyanate. Into this solution, a solution was added for 1 hour, which solution thus added was a solution of (i) and (ii) dissolved in methyl triglyme (50.0 g), which (i) was 40.0 g (0.040 mol) of a polyalkylene diol (product name: PTXG1000 manufactured by Asahi Kasei Co., Ltd., having an average molecular weight of 1000, which product is a polyalkylene diol represented by the following general formula (15):

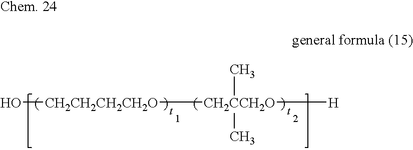

where t₁ and t₂ denote an integer of not less than 1), and (ii) was 10.0 g (0.01 mol) of a polycarbonate diol (product name PCDL T5651 manufactured by Asahi Kasei Co., Ltd., having an average molecular weight of 1000, which product is a polycarbonate diol represented by the following general formula (16):

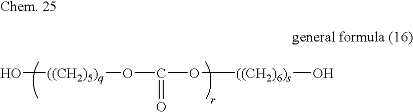

where q, r, and s denote integers of not less than 1).
This obtained a further solution, which was then heated to reflux for 5 hours.

Into this reactant solution, 16.2 g (0.100 mol) of dimethylol butanoic acid (2,2-bis(hydroxymethyl)butanoic acid) and methyl triglyme (16.2 g) were added, and this mixture was heated to reflux at 80° C. for 3 hours. To this solution, 17.5 g (0.1000 mol) of tolylene diisocyanate (mixture of 80% tolylene-2,4-diisocyanate and 20 tolylene-2,6-diisocyanate) and methyl triglyme (17.5 g) were added, and this solution was heated to reflux at 80° C. for 5 hours. Thereafter, 26.4 g (0.100 mol) of 5-(2,5-dioxotetrahydro-3-furanyl)-3-methyl-3-cyclohexene-1,2-dicarboxylic acid anhydride and methyl triglyme (26.4 g) were added. This mixture was heated to 180° C., and was reacted for 5 hours. As a result of this reaction, a solution of a urethane imide oligomer having a terminal acid anhydride was obtained. To the solution, 7.2 g (0.400 mol) of pure water was added and the solution was heated to reflux at 80° C. for 5 hours, so as to obtain a solution of urethane imide oligomer having a terminal carboxylic acid group. This synthetic resin is referred to as resin F.

### Synthesis Example 7

As a solvent for polymerization, methyl triglyme (17.5 g) was poured into a separable flask under positive nitrogen pressure. To this methyl triglyme, 17.5 g (0.1003 mol) of tolylene diisocyanate (mixture of 80 tolylene-2,4-diisocyanate and 20% tolylene-2,6-diisocyanate) was added, and this mixture was heated to 80° C. so as to dissolve tolylene diisocyanate. Into this solution, a solution was added for 1 hour, which solution thus added was a solution of 50.0 g (0.050 mol) of a polyalkylene dial (product name: PTXG1000 manufactured by Asahi Kasei Co., Ltd., having an average molecular weight of 1000 which product is a polyalkylene diol represented by the general formula (15)) dissolved in methyl triglyme (50.0 g). This obtained a further solution, which was then heated to reflux for 5 hours. To the reactant solution, 16.2 g (0.100 mol) of dimethylol butanoic acid (2,2-bis(hydroxymethyl)butanoic acid) and methyl triglyme (16.2 g) were added, and the solution was heated to reflux at 80° C. for 3 hours. Further to this solution, 17.5 g (0.1000 mol) of tolylene diisocyanate (mixture of 80% tolylene-2,4-diisocyanate and 20% tolylene-2,6-diisocyanate) and methyl triglyme (17.5 g) were added, and the solution was heated to reflux at 80° C. for 5 hours. Thereafter, 26.4 g (0.100 mol) of 5-(2,5-dioxotetrahydro-3-furanyl)-3-methyl-3-cyclohexene-1,2-dicarboxylic anhydride and methyl triglyme (26.4 g) were added. The solution was heated to 180° C., and was reacted for 5 hours. As a result of this reaction, a solution of a urethane imide oligomer having a terminal acid anhydride was obtained. To the solution, 7.2 g (0.400 mol) of pure water was added and the solution was heated to reflux at 80° C. for 5 hours. This produced a solution of a urethane imide oligomer having a terminal carboxylic acid group. This synthetic resin is referred to as resin G.

### Synthesis Example 8

As a solvent for polymerization, methyl triglyme (17.5 g) was poured into a separable flask under positive nitrogen pressure. To this methyl triglyme, 17.5 g (0.1003 mol) of tolylene diisocyanate (mixture of 80% tolylene-2,4-diisocyanate and 20% tolylene-2,6-diisocyanate) was added, and this mixture was heated to 80° C. so as to dissolve the tolylene diisocyanate. Into this solution, a solution was added for 1 hour, which solution thus added was a solution of 90.0 g (0.050 mol) of a polyalkylene diol (product name: PTXG1800 manufactured by Asahi Kasei Co., Ltd., having an average molecular weight of 1800, which product is a polyalkylene diol represented by the general formula (15)) dissolved in methyl triglyme (90.0 g). This obtained a further solution, which was then heated to reflux for 5 hours. Into the reaction solution, 16.2 g (0.100 mol) of dimethylol butanoic acid (2,2-bis(hydroxymethyl)butanoic acid) and methyl triglyme (16.2 g) was added, and the mixture was heated to reflux at 80° C. for 3 hours. To this solution, 17.5 g (0.1000 mol) of tolylene diisocyanate (mixture of 80% tolylene-2,4-diisocyanate and 20% tolylene-2,6-diisocyanate) and methyl triglyme (17.5 g) were added, and the mixture was heated to reflux at 80° C. for 5 hours. Thereafter, 26.4 g (0.100 mol) of 5-(2,5-dioxotetrahydro-3-furanyl)-3-methyl-3-cyclohexene-1,2-dicarboxylic acid anhydride and methyl triglyme (26.4 g) were added. The mixture was heated to 180° C., and was reacted for 5 hours. As a result of this reaction, a solution of a urethane imide oligomer having a terminal acid anhydride was obtained. To the solution, 7.2 g (0.400 mol) of pure water was added and the solution was heated to reflux at 80° C. for 5 hours, so as to obtain a solution of urethane imide oligomer having a terminal carboxylic acid group. This synthetic resin is referred to as resin H.

### Synthesis Example 9

As a solvent for polymerization, methyl triglyme (17.5 g) was poured into a separable flask under positive nitrogen pressure. To this methyl triglyme, 17.5 g (0.1003 mol) of tolylene diisocyanate (mixture of 80-tolylene-2,4-diisocyanate and 20% tolylene-2,6-diisocyanate) was added, and this mixture was heated to 80° C. so as to dissolve tolylene diisocyanate. Into this solution, a solution was added for 1 hour, which solution thus added was a solution of (i) and (ii), which (i) was 72.0 g (0.040 mol) of a polyalkylene diol (product name: PTXG1800 manufactured by Asahi Kasei Co., Ltd., having an average molecular weight of 1800, which product is a polyalkylene diol represented by the general formula (15)) and (ii) was 10.0 g (0.010 mol) of a polycarbonate diol (product name PCDL T5651 manufactured by Asahi Kasei Co., Ltd., having an average molecular weight of 1000, which product is a polycarbonate dial represented by the general formula (16)). This obtained a further solution, which was then heated to reflux for 5 hours.

Into the reaction solution, 16.2 g (0.100 mol) of dimethylol butanoic acid (2,2-bis(hydroxymethyl)butanoic acid) and methyl triglyme (16.2 g) was added, and the solution was heated to reflux at 80° C. for 3 hours. Further, to this solution, 17.5 g (0.1000 mol) of tolylene diisocyanate (mixture of 80% tolylene-2,4-diisocyanate and 20% tolylene-2,6-diisocyanate) and methyl triglyme (17.5 g) were added, and the solution was heated to reflux at 80° C. for 5 hours. Thereafter, 52.0 g (0.100 mol) of 2,2-bis[4-(3,4-dicarboxyphenoxy)phenyl]propane dianhydride (hereinafter referred to as BPADA) and methyl triglyme (52.0 g) were added. The mixture was heated to 180° C., and was reacted for 5 hours. As a result of the reaction, a solution of a urethane imide oligomer having a terminal acid anhydride was obtained. To the solution, 7.2 g (0.400 mol) of pure water was poured and the solution was heated to reflux at 80° C. for 5 hours, so as to obtain a solution of a urethane imide oligomer having a terminal carboxylic acid group. This synthetic resin is referred to as resin I.

### Synthesis Example 10

Water (0.400 mol) that was added to the solution of a urethane imide oligomer having a terminal acid anhydride after the synthesis reaction in Example 6 was changed to methanol (0.400 mol, 12.8 g). This half-esterified the terminal of the urethane imide oligomer. This synthetic resin is referred to as resin J.

### Examples 13 to 17

To the solution of a urethane imide oligomer having a terminal carboxylic acid group thus obtained in Synthesis Examples 6 to 10, a diamino compound, a photosensitive resin, a photopolymerization initiator, an organic solvent, and a thermosetting resin were added, so as to produce a photosensitive resin composition. The amounts contained of each of the constituent material with respect to a resin solid content and the types of material are as shown in Table 5. The amount of the solvent 1,2-bis(2-methoxyethoxy)ethane that is the solvent shown in the table is an entire solvent amount including the solvent contained in the synthesis resin solution and the like. Bubbles in the mixed solution were completely removed by a bubble-removing device in advance, and thereafter, the same evaluations as Examples 7 to 12 were carried out. Results of the evaluations are as shown in Table 6.

TABLE 5
unit: parts by weight

| | | Ex. 13 | Ex. 14 | Ex. 15 | Ex. 16 | Ex. 17 |
|---|---|---|---|---|---|---|
| Component | Resin F | 31.1 | | | | |
| (A) | Resin G | | 31.1 | | | |
| | Resin H | | | 32.7 | | |
| | Resin I | | | | 33.2 | |
| | Resin J | | | | | 31.4 |
| Component | 1,3-bis(3-aminophenoxy)benzene | 7.5 | 7.5 | 5.9 | 5.4 | 7.2 |
| (B) | | | | | | |
| Component | A-9300^{<1>} | 2.3 | 2.3 | 2.3 | 2.3 | 2.3 |
| (C) | BPE-1300^{<2>} | 17.0 | 17.0 | 17.0 | 17.0 | 17.0 |
| Component | IRGACURE819^{<3>} | 1.9 | 1.9 | 1.9 | 1.9 | 1.9 |
| (D) | | | | | | |
| Component | EPICLON | 5 | 5 | 5 | 5 | 5 |
| (E) | N-665^{<5>} | | | | | |
| Other | Barium sulfate | 28.9 | 28.9 | 28.9 | 28.9 | 28.9 |
| Components | AEROGIL R-974^{<4>} | 2.6 | 2.6 | 2.6 | 2.6 | 2.6 |
| | CR-741^{<6>} | 8.7 | 8.7 | 8.7 | 8.7 | 8.7 |
| | 1,2-bis(2-methoxyethoxy)ethane | 100 | 100 | 100 | 100 | 100 |
| | Solid content | 50 | 50 | 51 | 51 | 50 |
| | concentration of | | | | | |
| | photosensitive resin | | | | | |
| | composition solution | | | | | |

^{<1>}Product Name: NK ESTER A-9300 (ethoxylated isocyanuric acid triacrylate), manufactured by Nakamura Chemical Co., Ltd.
^{<2>}Ethoxylated bisphenol A diacrylate, manufactured by Nakamura Chemical Co., Ltd. (molecular weight: 1684)
^{<3>}Photopolymerization Initiator, manufactured by CIBA specialty chemicals Inc.
^{<4>}Silica particules, manufactured by Nippon AEROSIL CO., LTD
^{<5>}Product name of cresol novolac type multifunctional epoxy resin, manufactured by Dainippon Ink and Chemicals
^{<6>}Product name of phosphoric ester-based flame retardant, manufactured by Daihachi Chemical Industry Co., Ltd.

TABLE 6

| | Ex. | | Ex. | | Ex. | Comparative |
|---|---|---|---|---|---|---|
| Evaluated Items | 13 | Ex. 14 | 15 | Ex. 16 | 17 | Example 7 |
| Photosensitivity | ◯ | ◯ | ◯ | ◯ | ◯ | ◯ |
| Adhesiveness | ◯ | ◯ | ◯ | ◯ | ◯ | ◯ |
| Flexibility | ◯ | ◯ | ◯ | ◯ | ◯ | ◯ |
| Moisture-resistant | ◯ | ◯ | ◯ | ◯ | ◯ | X |
| Insulating property | | | | | | |
| Wettability | 36 | 38 | 38 | 38 | 38 | Not more than |
| (mN/m) | | | | | | 30 |

### Synthesis Example 11

As a solvent for polymerization, methyl triglyme (17.5 g) was poured into a separable flask under positive nitrogen pressure. To this methyl triglyme, 17.5 g (0.1003 mol) of tolylene diisocyanate (mixture of 80 tolylene-2,4-diisocyanate and 20% tolylene-2,6-diisocyanate) was added, and this mixture was heated to 80° C. so as to dissolve tolylene diisocyanate. Into this solution, a solution was added for 1 hour, which solution thus added was a solution of (i), (ii) and (iii) dissolved in methyl triglyme (50.0 g), which (i) was 15.0 g (0.015 mol) of a polyalkylene diol (product name: PTXG1000 manufactured by Asahi Kasei Co., Ltd., having an average molecular weight of 1000, which product is a polyalkylene diol represented by the following general formula (15):

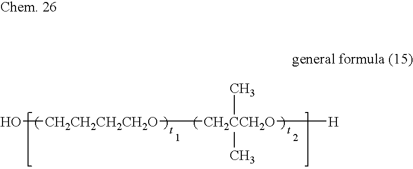

where t₁ and t₂ independently denote an integer of not less than 1),
(ii) was 10.0 g (0.01 mol) of a polycarbonate dial (product name PCDL T5651 manufactured by Asahi Kasei Co., Ltd., having an average molecular weight of 1000, which product is a polycarbonate diol represented by the following general formula (16):

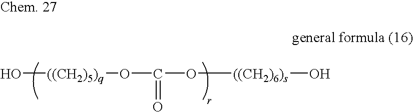

where q, r, and s independently denote an integer of not less than 1), and
(iii) was 8.1 g (0.050 mol) of dimethylol butanoic acid (2,2-bis(hydroxymethyl)butanoic acid).
This obtained a further solution, which was then heated to reflux for 5 hours. The reactant solution is referred to as intermediate E.

To another reaction apparatus different from the reaction apparatus used in the foregoing reaction, 52.0 g (0.100 mol) of 2,2-bis[4-(3,4-dicarboxyphenoxy)phenyl]propane dianhydride (hereinafter referred to as BPADA) and methyl triglyme (52.0 g) were added. This mixture was heated to 80° C., and BPADA was dispersed in methyl triglyme.

The intermediate E was added to the solution over 1 hour, so as to react with the solution. After the intermediate E was added, the solution was heated to 180° C., and the solution reacted with the intermediate E for 5 hours. As a result of this reaction, a urethane imide oligomer having a terminal acid anhydride was obtained. To this solution, 7.2 g (0.400 mol) of pure water was added, and the solution was heated to reflux at 80° C. for 5 hours. This produced a solution of a urethane imide oligomer having a terminal carboxylic acid group. This synthetic resin is referred to as resin K.

### Synthesis Example 12

As a solvent for polymerization, methyl triglyme (17.5 g) was poured into a separable flask under positive nitrogen pressure. To this methyl triglyme, 17.5 g (0.1003 mol) of tolylene diisocyanate (mixture of 80 tolylene-2,4-diisocyanate and 20% tolylene-2,6-diisocyanate) was added, and this mixture was heated to 80° C. so as to dissolve tolylene diisocyanate. Into the solution, a solution was added for 1 hour, which solution thus added was a solution of (i), (ii) and (iii) dissolved in methyl triglyme (50.0 g), which (i) was 27.0 g (0.015 mol) of a polyalkylene diol (product name: PTXG1800 manufactured by Asahi Kasei Co., Ltd., having an average molecular weight of 1800, which product is a polyalkylene diol represented by the general formula (15)), (ii) was 20.0 g (0.010 mol) of a polycarbonate diol (product name PCDL T5652 manufactured by Asahi Kasei Co., Ltd., having an average molecular weight of 2000, which product is a polycarbonate diol represented by the general formula (16)), and (iii) was 8.1 g (0.050 mol) of dimethylol butanoic acid (2,2-bis(hydroxymethyl)butanoic acid). This obtained a further solution, which was then heated to reflux for 5 hours. The reactant solution is referred to as intermediate F.

To another reaction apparatus different from the reaction apparatus used in the foregoing reaction, 52.0 g (0.100 mol) of 2,2-bis[4-(3,4-dicarboxyphenoxy)phenyl]propane dianhydride (hereinafter referred to as SPADA) and methyl triglyme (52.0 g) were added. The mixture was heated to 80° C., and BPADA was dispersed in methyl triglyme.

The intermediate F was added to the solution over 1 hour, so as to react with the solution. After the intermediate F was added, the solution was heated to 180° C., and the solution was reacted with the intermediate F for 5 hours. As a result of this reaction, a solution of a urethane imide oligomer having a terminal acid anhydride was obtained. To this solution, 7.2 g (0.400 mol) of pure water was added, and further the solution was heated to reflux at 80° C. for 5 hours, so as to obtain a solution of a urethane imide oligomer having a terminal carboxylic acid group. This synthetic resin is referred to as resin L.

### Synthesis Example 13

As a solvent for polymerization, methyl triglyme (17.5 g) was poured into a separable flask under positive nitrogen pressure. To this methyl triglyme, 17.5 g (0.1003 mol) of tolylene diisocyanate (mixture of 80 tolylene-2,4-diisocyanate and 20% tolylene-2,6-diisocyanate) was added, and this mixture was heated to 80° C. so as to dissolve tolylene diisocyanate. Into this solution, a solution was added for 1 hour, which solution thus added was a solution of (i) and (ii) dissolved in methyl triglyme (50.0 g), which (i) was 50.0 g (0.025 mol) of a polycarbonate diol (product name PCDL T5652 manufactured by Asahi Kasei Co., Ltd., having an average molecular weight of 2000, which product is a polycarbonate diol represented by the general formula (16)), and (ii) was 8.1 g (0.050 mol) of dimethylol butanoic acid (2,2-bis(hydroxymethyl)butanoic acid). This obtained a further solution, which was then heated to reflux for 5 hours. The reactant solution is referred to as intermediate G.

To another reaction apparatus different from the reaction apparatus used in the foregoing reaction, 52.0 g (0.100 mol) of 2,2-bis[4-(3,4-dicarboxyphenoxy)phenyl]propane dianhydride (hereinafter referred to as BPADA) and methyl triglyme (52.0 g) were added. The mixture was heated to 80° C., and BPADA was dispersed in methyl triglyme.

The intermediate G was added to the solution over 1 hour, so as to react with the solution. After the intermediate G was added, the solution was heated to 180° C., and the solution was reacted with the intermediate G for 5 hours. As a result of the reaction, a solution of a urethane imide oligomer having a terminal acid anhydride was obtained. To this solution, 7.2 g (0.400 mol) of pure water was added, and the solution was heated to reflux at 80° C. for 5 hours, so as to obtain a solution of a urethane imide oligomer having a terminal carboxylic acid group. This synthetic resin is referred to as resin M.

### Synthesis Example 14

As a solvent for polymerization, methyl triglyme (17.5 g) was poured into a separable flask under positive nitrogen pressure. To this methyl triglyme, 20.7 g (0.1004 mol) of norbornene diisocyanate was added, and the mixture was heated to 80° C. so as to dissolve the norbornene diisocyanate. Into the solution, a solution was added for 1 hour, which solution thus added was a solution of (i) and (ii) dissolved in methyl triglyme (50.0 g), which (i) was 50.0 g (0.025 mol) of a polycarbonate diol (product name PCDL T5652 manufactured by Asahi Kasei Co., Ltd., having an average molecular weight of 2000, which product is a polycarbonate diol represented by the general formula (16)), and (ii) was 8.1 g (0.050 mol) of dimethylol butanoic acid (2,2-bis(hydroxymethyl)butanoic acid). This obtained a further solution, which was then heated to reflux for 5 hours. The reactant solution is referred to as intermediate H.

To another reaction apparatus different from the reaction apparatus used in the foregoing reaction, 52.0 g (0.100 mol) of 2,2-bis[4-(3,4-dicarboxyphenoxy)phenyl]propane dianhydride (hereinafter referred to as BPADA) and methyl triglyme (52.0 g) were added. The mixture was heated to 80° C., and BPADA was dispersed in methyl triglyme.

The intermediate H was added to the solution over 1 hour, so to react with the solution. After the intermediate H was added, the solution was heated to 180° C., and the solution was reacted with the intermediate H for 5 hours. As a result of the reaction, a solution of a urethane imide oligomer having a terminal acid anhydride was obtained. To this solution, 7.2 g (0.400 mol) of pure water was added, and the solution was heated to reflux at 80° C. for 5 hours, so as to obtain a solution of a urethane imide oligomer having a terminal carboxylic acid group. This synthetic resin is referred to as resin N.

### Synthesis Example 15

Water (0.400 mol) that was added to the urethane imide oligomer having a terminal acid anhydride after reaction in Synthesis Example 11 was changed to 12.8 g (0.400 mol) of methanol. This half-esterified the terminal of the urethane imide oligomer. This synthesis resin is referred to as resin O.

### Examples 18 to 22

To the urethane imide oligomer having a terminal carboxylic acid group obtained in Synthesis Examples 11 to 15, a diamino compound, a photosensitive resin, a photopolymerization initiator, an organic solvent, and a thermosetting resin were added, so as to produce a photosensitive resin composition. The amounts contained of each of the constituent material with respect to a resin solid content and the types of material are as shown in Table 7. The amount of the solvent 1,2-bis(2-methoxyethoxy)ethane that is the solvent shown in the table is an entire solvent amount including the solvent contained in the synthesis resin solution and the like. Bubbles in the mixed solution were completely removed by a bubble-removing device in advance, and thereafter, the same evaluations as Examples 7 to 12 were carried out. Results of the evaluations are as shown in Table 8.

TABLE 7
unit: parts by weight

| | | Ex. 18 | Ex. 19 | Ex. 20 | Ex. 21 | Ex. 22 |
|---|---|---|---|---|---|---|
| Component | Resin K | 31.0 | | | | |
| (A) | Resin L | | 31.0 | | | |
| | Resin M | | | 31.0 | | |
| | Resin N | | | | 31.0 | |
| | Resin O | | | | | 31.0 |
| Component | 1,3-bis(3-aminophenoxy)benzene | 2.4 | 1.9 | 1.9 | 1.8 | 2.4 |
| (B) | | | | | | |
| Component | A-9300^{<1>} | 2.3 | 2.3 | 3.6 | 3.6 | 2.3 |
| (C) | BPE-1300^{<2>} | 17.0 | 17.0 | 17.0 | 17.0 | 17.0 |
| Component | IRGACURE819^{<3>} | 1.9 | 1.9 | 1.9 | 1.9 | 1.9 |
| (D) | | | | | | |
| Component | EPICLON | — | — | 5 | 5 | — |
| (E) | N-665^{<5>} | | | | | |
| Other | Barium sulfate | 28.9 | 28.9 | 28.9 | 28.9 | 28.9 |
| Components | AEROGIL R-974^{<4>} | 2.6 | 2.6 | 2.6 | 2.6 | 2.6 |
| | CR-741^{<6>} | 8.7 | 8.7 | 8.7 | 8.7 | 8.7 |
| | 1,2-bis(2-methoxyethoxy)ethane | 95 | 95 | 100 | 100 | 95 |
| | Solid content | 50 | 50 | 50 | 50 | 50 |
| | concentration of | | | | | |
| | photosensitive resin | | | | | |
| | composition solution | | | | | |

^{<1>}Product Name: NK ESTER A-9300 (ethoxylated isocyanuric acid triacrylate), manufactured by Nakamura Chemical Co., Ltd.
^{<2>}Ethoxylated bisphenol A diacrylate, manufactured by Nakamura Chemical Co., Ltd. (molecular weight: 1684)
^{<3>}Photopolymerization Initiator, manufactured by CIBA specialty chemicals Inc.
^{<4>}Silica particules, manufactured by Nippon AEROSIL CO., LTD
^{<5>}Product name of cresol novolac type multifunctional epoxy resin, manufactured by Dainippon Ink and Chemicals
^{<6>}Product name of phosphoric ester-based flame retardant, manufactured by Daihachi Chemical Industry Co., Ltd.

TABLE 8

| | Ex. | | Ex. | | | Comparative |
|---|---|---|---|---|---|---|
| Evaluated Items | 18 | Ex. 19 | 20 | 21 | Ex. 22 | Example 7 |
| Photosensitivity | ◯ | ◯ | ◯ | ◯ | ◯ | ◯ |
| Adhesiveness | ◯ | ◯ | ◯ | ◯ | ◯ | ◯ |
| Flexibility | ◯ | ◯ | ◯ | ◯ | ◯ | ◯ |
| Moisture-resistant | ◯ | ◯ | ◯ | ◯ | ◯ | X |
| Insulating property | | | | | | |
| Solder thermal | — | — | ◯ | ◯ | — | — |
| resistance | | | | | | |
| Wettability | 38 | 38 | 38 | 36 | 38 | Not more than |
| (mN/m) | | | | | | 30 |

### Comparative Example 7

In a flask made of glass and which has a capacity of 2000 ml, 176.09 g (598.5 mmol) of 3,3′,4,4′-biphenyl tetracarboxylic acid dianhydride and 254.26 g of methyl triglyme were poured, and the mixture was heated to 180° C. and stirred under a nitrogen atmosphere. Into the mixture, 250.25 g (301.5 mmol) of α,ω-bis(3-aminopropyl)polydimethyl siloxane (KF8010, manufactured by Shin-Etsu Chemical Co., Ltd., having an average molecular weight of 830) and 100 g of methyl triglyme were added, and this mixture was evenly stirred at 180° C. for 60 minutes. Furthermore, 42.51 g (148.5 mmol) of bis(3-carboxy,4-aminophenyl)methane and 100 g of methyl triglyme were added to the reaction solution, and thereafter heated to 180° C. and stirred for 6 hours. This solution is referred to as a half-ester solution.

Separately to the foregoing reaction apparatus, 126.9 g (300 mmol) of tris(2-acryloyloxyethyl)isocyanurate [M-315 manufactured by Toagosei Co., Ltd.] and 120 g of methyl diglyme were poured into a glass container which blocks light and has a capacity of 500 ml. The mixture therein was stirred and dissolved at room temperature under a nitrogen atmosphere. Next, 83.0 g (100 mmol) of α,ω-bis(3-aminopropyl)polydimethylsiloxane (KF8010, manufactured by Shin-Etsu Chemical Co., Ltd., having an average molecular weight of 830) and 52.9 g of diglyme were added thereto. This mixture was further stirred for 2 more hours, so as to obtain a reaction liquid of a photosensitive monomer in which tris(2-acryloyloxyethyl) isocyanurate is added to both ends of diaminopolysiloxane, respectively. This solution is referred to as a photosensitive monomer solution.

Next, 1.25 g of 2-hydroxyethyl methacrylate and 15.39 g of the photosensitive monomer solution were added to 50 g of the half-ester solution. Further to the mixture, 2.57 g of Irgacures 907 (manufactured by CIBA specialty chemicals Inc.) and 0.51 g of 2,4-diethylthioxanthone (DETX manufactured by Nippon Kayaku Co., Ltd.) were added as photopolymerization initiators, 1.02 g of p-dimethylaminobenzoic acid ethyl ester (EDMAB, manufactured by Nippon Kayaku Co., Ltd.), 0.13 g of a silicon-based antifoaming agent (DB-100, manufactured by Dow Corning Co., Ltd), 2.56 g of AEROSIL (average particle diameter: 0.01 μm), and 5.19 g of talc (average particle diameter: 1.8 μm) were added into the mixture and stirred at room temperature (25° C.) for 2 hours. The stirred mixture was left to stand for 1 hour, and thereafter was evenly mixed with the three-roll, thereby obtaining a photosensitive imidosiloxane oligomer composition.

At room temperature, 50 g of the obtained photosensitive imidosiloxane oligomer composition, 3.2 g of epoxy resin (EPICOAT 152, manufactured by Japan Epoxy Resin Co., Ltd.), and 0.032 g of 2-ethyl-4-methylimidazole were mixed together and stirred for 1 hour, thereby obtaining a composition.

This obtained composition was evaluated in its physical properties in the same method as Example 7. Results thereof are shown in Tables 4, 6, and 8.

The present invention includes a photosensitive resin composition in which at least a (A) urethane imide oligomer having a terminal carboxylic acid group, a (B) diamino compound, a (C) photosensitive resin, and a (D) photopolymerization initiator are included.

The photosensitive resin composition can also further include a (E) thermosetting resin.

Furthermore, the (A) urethane imide oligomer having a terminal carboxylic acid group can be a urethane imide oligomer having a structure represented by a general formula (19), which urethane imide oligomer is obtained by reacting (i) a terminal isocyanate compound represented by the following general formula (18):

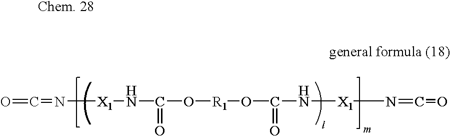

where R₁ denotes a polycarbonate skeleton and/or a polyalkylene skeleton; each X₁ independently denote a bivalent organic group; and each of 1 and m in the formula independently is an integer of 1 to 20, and
(ii) a tetracarboxylic acid dianhydride represented by the following general formula (3):

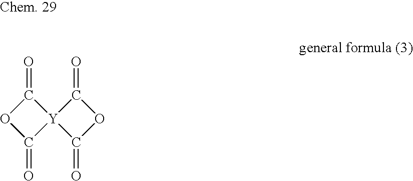

where Y denotes a quadrivalent organic group,
in such a manner that satisfy: a number of moles of the terminal isocyanate compound/the number of moles of the tetracarboxylic acid dianhydride≦0.80, and thereafter reacting a resultant with water (H₂O) and/or a primary alcohol (R₃—OH). The structure of the general formula (19) is as represented as follows:

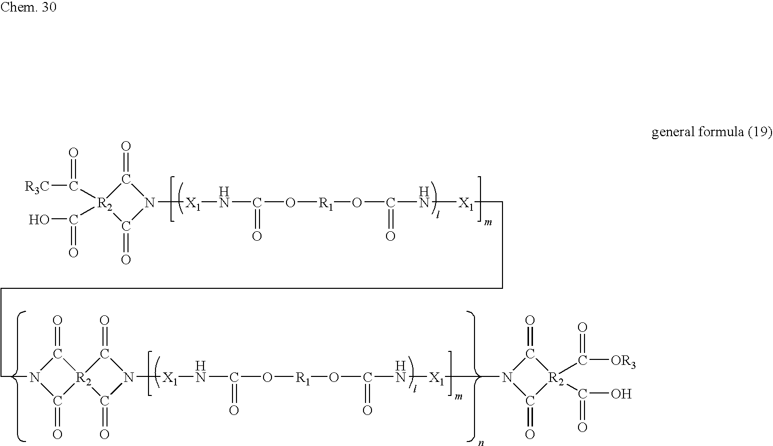

where R₁ denotes a polycarbonate skeleton and/or a polyalkylene skeleton; each Xᵢ independently denotes a bivalent organic group; each R₂ independently denotes a quadrivalent organic group; each R₃ independently denotes a hydrogen or alkyl group; further, 1 and m are independently an integer of 1 to 20, and n is an integer not less than 0.

Furthermore, the (B) diamino compound may be an aromatic diamine represented by the following general formula (7):

Chem. 31

H₂N—R₄—NH₂ general formula (7)

where R₄ is a bivalent organic group.

The (C) photosensitive resin can be a photosensitive resin composition which includes at least one unsaturated double bond in a molecule.

Moreover, the (E) thermosetting resin can be an epoxy resin.

Furthermore, the components (A) and (B) of the photosensitive resin composition is preferably contained in such amounts satisfying that (a)/((b)+(c))=not less than 0.80 but not more than 1.20, where:

(a) is a molar quantity of a dianhydride in the component (A) in the photosensitive resin composition;

(b) is a molar quantity of a terminal isocyanate compound in the component (A) in the photosensitive resin composition; and

(c) is a molar quantity of a diamine in the component (B) in the photosensitive resin composition.

It is preferable that the component (A), the component (B), the component (C), and the component (D) are included in the photosensitive resin composition in such a manner that the component (C) is included by 10 parts by weight to 200 parts by weight and the component (D) is included by 0.1 parts by weight to 50 parts by weight, with respect to a total solid content of the component (A) and the component (B) being 100 parts by weight.

Furthermore, it is preferable that the amount included of the (E) thermosetting resin is 0.5 parts by weight to 100 parts by weight, with respect to a total solid content of the component (A), the component (B), the component (C), and the component (D) being 100 parts by weight.

Moreover, the present invention includes a photosensitive resin composition solution obtained by dissolving the photosensitive resin composition in an organic solvent.

Moreover, the present invention includes a cured film obtained by curing the photosensitive resin composition.

Moreover, the present invention includes an insulating film prepared from the photosensitive resin composition.

Moreover, the present invention includes a printed wiring board with an insulating film, in which a printed wiring board is covered with the photosensitive resin composition.

Moreover, the present invention includes a photosensitive resin composition that includes at least a (A) terminal carboxylic acid compound having a carboxyl group on a side chain and terminal thereof, a (B) diamino compound, a (C) photosensitive resin, and a (D) photopolymerization initiator, which terminal carboxylic acid compound is represented by the following general formula (20):

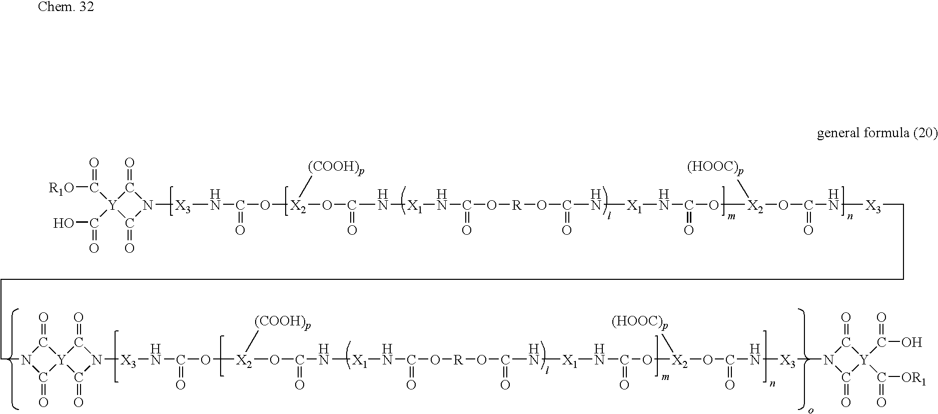

where R denotes a polycarbonate skeleton and/or a polyalkylene skeleton; each X₁ and X₃ independently denotes a bivalent organic group; each X₂ independently denotes an organic group which includes at least one carboxylic acid group; each R₁, independently denotes a hydrogen or alkyl group; Y is a quadrivalent organic group; l, m, and n independently denote an integer of 1 to 20, O denotes an integer of 0 to 20, and p denotes an integer of 1 to 3.

Furthermore, the photosensitive resin composition may include a (E) thermosetting resin.

The (A) terminal carboxylic acid compound may be obtained by reacting a (a) polyol represented by the following general formula (1):

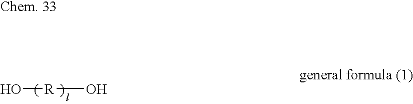

where R denotes a polycarbonate skeleton and/or a polyalkylene skeleton; and 1 is an integer of 1 to 20,
a (b) isocyanate represented by the following general formula (21):

Chem. 34

O═C═N—X₁—N═C═O general formula (21)

where X₁ denotes a bivalent organic group,
a (c) dihydroxycarboxylic acid compound represented by the following general formula (22):

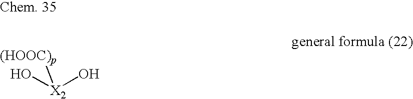

where X₂ is an organic group, and p is an integer of 1 to 3, and
a (d) isocyanate represented by the following general formula (23):

Chem. 36

O═C═N—X₃—N═C═O general formula (23)

where X₃ denotes a bivalent organic group,
so as to obtain a (e) terminal isocyanate compound represented by the following general formula (24):

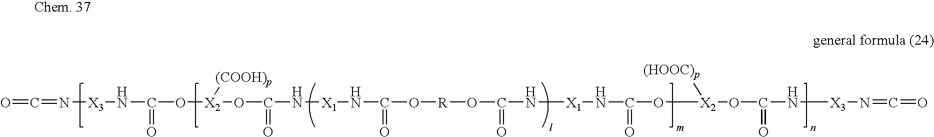

where R denotes a polycarbonate skeleton and/or a polyalkylene skeleton; each X₁ and X₃ independently denotes a bivalent organic group; each X₂ independently denotes an organic group having at least one carboxylic acid group; 1, m, and n independently is an integer of 1 to 20, and p is an integer of 1 to 3,
and further reacting the (e) terminal isocyanate compound with a (f) tetracarboxylic acid dianhydride represented by the following general formula (3):

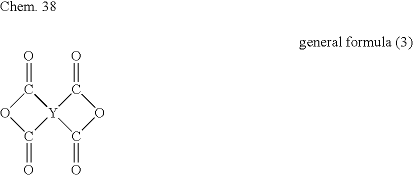

where Y is a quadrivalent organic group, and
(g) water and/or alcohol, so as to obtain a photosensitive resin composition.

The (B) diamino compound may be an aromatic diamine represented by the following general formula (7):

Chem. 39

H₂N—R₄—NH₂ general formula (7)

where R₄ is a bivalent organic group.

The (C) photosensitive resin preferably is a photosensitive resin component having at least one unsaturated double bond in a molecule.

Furthermore, the (E) thermosetting resin is preferably an epoxy resin.

Furthermore, the component (B) is preferably included in the photosensitive resin component in such a manner that a molar ratio of (2)/((1)/(2))=not less than 0.50 but not moer than 1.00, where:

(1) is a molar quantity of the (f) tetracarboxylic acid used for synthesis of component (A) in the photosensitive resin composition, and
(2) is a molar quantity of component (B) in the photosensitive resin composition.

Furthermore, it is preferable that the components (A), (B), (C), and (D) are included in the photosensitive resin composition in such a manner that the component (C) is included by 10 parts by weight to 200 parts by weight and the component (D) is included by 0.1 to 50 parts by weight, with respect to a total solid content of the component (A) and the component (B) being 100 parts by weight.

It is also preferable that the amount included of the (E) thermosetting resin is 0.5 parts by weight to 100 parts by weight, with respect to a total solid content of the components (A), (B), (C), and (D) being 100 parts by weight.

Moreover, the present invention includes a photosensitive resin composition solution obtained by dissolving the foregoing photosensitive resin composition in an organic solvent.

Furthermore, the present invention includes a cured product obtained by curing the foregoing photosensitive resin composition.

Furthermore, the present invention includes an insulating film prepared from the photosensitive resin composition.

Furthermore, the invention of the present application includes a printed wiring board with an insulating film, in which a printed wiring board is covered with the insulating film.

The terminal carboxylic acid component represented by the general formula (20) is synthesized by reacting (i) a terminal isocyanate compound represented by the general formula (24), (ii) the tetracarboxylic acid dianhydride, and (iii) water or alcohol.

The terminal isocyanate compound represented by the general formula (24) is obtained by reacting (i) a polyol, (ii) a isocyanate, and (iii) a dihydroxy carboxylic acid compound.

As the dihydroxycarboxylic acid compound represented by the general formula (22), a compound such as dimethylol propionic acid (2,2-bis(hydroxymethyl) propionic acid), dimethylol butanoic acid (2,2-bis(hydroxymethyl) butanoic acid), 2,3-dihydroxybenzoic acid, 2,4-dihydroxybenzoic acid, 2,5-dihydroxybenzoic acid, 2,6-dihydroxybenzoic acid, 3,4-dihydroxybenzoic acid, or 3,5-dihydroxybenzoic acid is suitably usable. Use of such a dihyroxycarboxylic acid is preferable since this allows control of a carboxylic acid group content in a molecule skeleton.

The terminal isocyanate compound of the present invention represented by the general formula (24), is synthesized by the following method:

Step 1: A polyol represented by the general formula (1) (more specifically, a diol compound) is reacted with an isocyanate represented by the general formula (21). Reaction is carried out without a solvent or in an organic solvent in such a manner that the polycarbonate diols and the diisocyanates are included so as to satisfy a ratio of: the number of hydroxyl groups and isocyanate groups of: isocyanate group/hydroxyl group=not less than 1.90 but not more than 2.10. This as a result obtains an intermediate A.

Step 2: The intermediate A obtained in Step 1 is reacted with a dihydroxycarboxylic acid compound represented by the general formula (22). The reaction is carried out without a solvent or in an organic solvent in such a manner that intermediate A and the dihydroxycarboxylic acid compound are included so as to satisfy a ratio of the number of isocyanate groups in the intermediate A and the number of hydroxyl groups in the dihydroxycarboxylic acid compound of: isocyanate group/hydroxyl group not less than 1.90 but not more than 2.10. This thus obtains an intermediate B.

Step 3: The intermediate B obtained in Step 2 is reacted with an isocyanate represented by the general formula (23). The reaction is carried out without a solvent or in an organic solvent in such a manner that the intermediate B and the isocyanate having the general formula (23) are included so as to satisfy a ratio of the number of hydroxyl groups in the intermediate B and the number of isocyanate groups in the isocyanate of: isocyanate group/hydroxyl group=not less than 1.90 but not more than 2.10. This thus obtains a terminal isocyanate compound represented by the general formula (24).

Next, a tetracarboxylic acid dianhydride is reacted with the obtained terminal isocyanate compound, so as to obtain a terminal carboxylic anhydride represented by the following general formula (25), which terminal carboxylic anhydride has a carboxylic acid on its side chain:

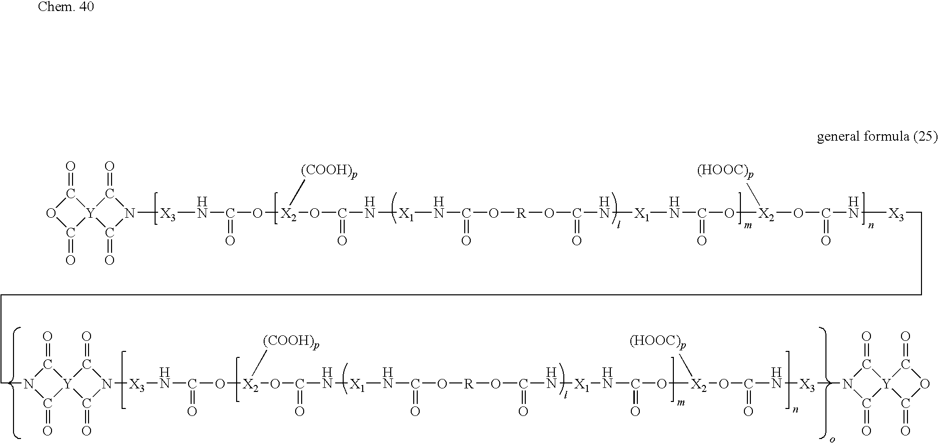

where R denotes a polycarbonate skeleton and/or a polyalkylene skeleton; each X₁ and X₃ independently denotes a bivalent organic group; each X₂ independently denotes an organic group having at least one carboxylic acid group; and, 1, m, and n independently denote an integer of 1 to 20, O denotes an integer of 0 to 20, and p denotes an integer of 1 to 3.

A terminal carboxylic acid compound is obtainable by ring-opening the foregoing terminal carboxylic anhydride by use of water or alcohol.

Moreover, the terminal carboxylic acid compound that has a carboxylic acid group on a side chain and terminal thereof is obtained by reacting water or alcohol with the terminal carboxylic anhydride having a carboxylic acid group on its side chain. Alcohol that includes an alkylene group is preferably used as the alcohol thus used. For example, methanol, ethanol, propanol, butanol, or like alcohol is preferably used. However, it is preferable to have the terminal carboxylic anhydride react with water, since the reaction with the water allows easy progressing of sufficient reaction upon heating and curing the photosensitive resin component, even if a curing temperature of the photosensitive resin component is low. A temperature for reacting the terminal carboxylic anhydride with water or alcohol is preferably not more than 150° C., and is more preferably not more than 120° C.

Various methods can be used for the reaction. Particularly, it is preferable to heat and reflux the terminal carboxylic anhydride having a carboxylic acid group on its side chain, in an organic solvent solution that includes water and/or alcohol.

The amount of water and/or alcohol reacted at this time is preferably the same or more than a molar quantity of the tetracarboxylic anhydride used in production of the terminal carboxylic anhydride. Particularly, it is preferable to have a molar quantity of not less than 1.5 times more than that of the tetracarboxylic acid dianhydride thus used, in view of efficient reaction.

The polyol (more specifically, the diol compound) represented by the general formula (1) can be a polycarbonate diol represented by the following general formula (26), which has a carbonate skeleton:

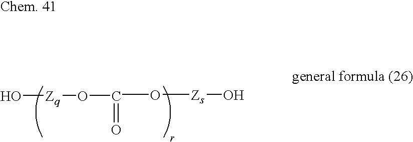

where Z denotes one or more type(s) of group(s) selected from the group consisting of: —CH₂—, —CH₂C(CH₃)₂CH₂—, —CH₂CH(CH₃)CH₂—, and —CH₂CH(CH₃)CH₂CH₂—; q and s independently are an integer of 1 to 30; and r is an integer of not less than 1, and/or

a polyalkylene diol represented by the following general formula (27):

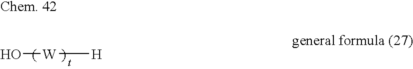

where W denotes one or more type(s) of organic group(s) selected from the group consisting of the following general formulae (1):

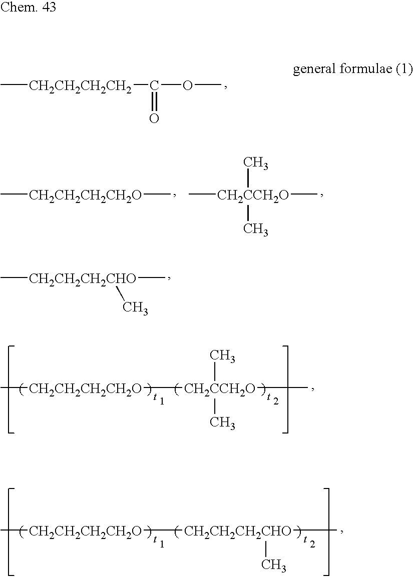

where t₁ and t₂ independently are an integer of not less than 1.

Furthermore, examples of product names of the polyalkylene dial encompass: PTXG1000, PTXG1500, PTGX1800, FAS PTMG-1000, FAS PTMG-1800, and FAS PTMG-2000, each of which are products manufactured by Asahi Kasei Co., Ltd.

In the present invention, it is particularly preferable to use a polyalkylene diol as an essential component in developing with use of an alkaline aqueous solution.

1. A polyimide precursor composition comprising at least:
a (A) urethane imide oligomer having a terminal carboxylic acid group; and
a (B) diamino compound and/or isocyanate compound.

2. The polyimide precursor composition according to claim 1, wherein the (A) urethane imide oligomer having a terminal carboxylic acid group is a tetracarboxylic acid urethane imide oligomer.

3. The polyimide precursor composition according to claim 1, wherein the (A) urethane imide oligomer having a terminal carboxylic acid group is obtainable by (i) reacting at least a (a) diol compound and a (b) diisocyanate compound so as to synthesize a terminal isocyanate compound, (ii) reacting the synthesized terminal isocyanate compound with a (c) tetracarboxylic acid dianhydride represented by a general formula (3) so as to synthesize a urethane imide oligomer having a terminal acid anhydride, and (iii) reacting the synthesized urethane imide oligomer having a terminal acid anhydride with (d) water and/or primary alcohol, the (a) diol compound being represented by the following general formula (1):
Chem 1
HOR_{I}OH general formula (1)
where R denotes a bivalent organic group; and I denotes an integer of 1 to 20,
the (b) diisocyanate compound being represented by the following general formula (2):
Chem. 2
O═C═N—X—N═C═O general formula (2)
where X denotes a bivalent organic group, and
the (c) tetracarboxylic acid dianhydride being represented by the following general formula (3): 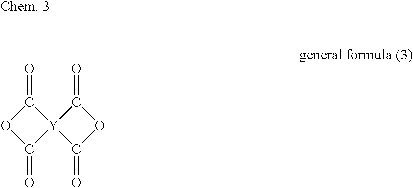
where Y denotes a quadrivalent organic group.

4. The polyimide precursor composition according to claim 1, wherein the (a) diol compound includes at least a polycarbonate diol represented by the following general formula (4): 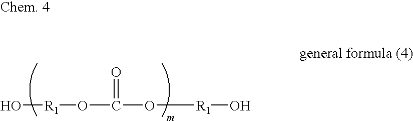
where each R₁ independently denote a bivalent organic group; and m denotes an integer of 1 to 20.

5. The polyimide precursor composition according to claim 1, wherein the (A) urethane imide oligomer having a terminal carboxylic acid group further includes a carboxyl group in its side chain.

6. A photosensitive resin composition comprising at least:
a polyimide precursor composition as set forth in claim 1;
a (C) photosensitive resin; and
a (D) photopolymerization initiator.

7. The photosensitive resin composition according to claim 6, wherein the (A) urethane imide oligomer having a terminal carboxylic acid group, the (B) diamino compound and/or isocyanate compound, the (C) photosensitive resin, and the (D) photopolymerization initiator are included in the photosensitive resin composition in such a manner that the (C) photosensitive resin is included by 10 parts by weight to 200 parts by weight and the (D) photopolymerization initiator is included by 0.1 parts by weight to 50 parts by weight, with respect to a total solid content of the (A) urethane imide oligomer having a terminal carboxylic acid and the (B) diamino compound and/or isocyanate compound being 100 parts by weight.

8. The photosensitive resin composition according to claim 6, further comprising a (E) thermosetting resin.

9. The photosensitive resin composition according to claim 8, wherein the (E) thermosetting resin is comprised by 0.5 parts by weight to 100 parts by weight, with respect to a total solid content of the (A) urethane imide oligomer having a terminal carboxylic acid group, the (B) diamino compound and/or isocyanate compound, the (C) photosensitive resin, and the (D) photopolymerization initiator being 100 parts by weight.

10. A thermosetting resin composition comprising at least:
a polyimide precursor composition as set forth in claim 1; and
a (E) thermosetting resin.

11. The thermosetting resin composition according to claim 10, wherein the (E) thermosetting resin is comprised by 0.5 parts by weight to 100 parts by weight, with respect to a total solid content of the (A) urethane imide oligomer having a terminal carboxylic acid group, and the (B) diamino compound and/or isocyanate compound being 100 parts by weight.

12. A polyimide precursor composition solution obtained by dissolving into an organic solvent a polyimide precursor composition as set forth in claim 1.

13. A resin film obtained by (i) applying to a substrate surface a polyimide precursor composition solution as set forth in claim 12, then (ii) drying the applied solution.

14. An insulating film obtained by curing a resin film as set forth in claim 13.

15. A printed wiring board with an insulating film, in which the insulating film is an insulating film as set forth in claim 14 and covers the printed wiring board.

16. A polyimide precursor composition solution obtained by dissolving into an organic solvent a photosensitive resin composition as set forth in claim 6.

17. A polyimide precursor composition solution obtained by dissolving into an organic solvent a thermosetting resin composition as set forth in claim 10.
